(19) United States
(12) Patent Application Publication
(10) Pub. No.: US 2024/0402554 A1
(43) Pub. Date: Dec. 5, 2024

(54) DISPLAY DEVICE

(71) Applicant: Japan Display Inc., Tokyo (JP)

(72) Inventor: Akihiro HANADA, Tokyo (JP)

(73) Assignee: Japan Display Inc., Tokyo (JP)

(21) Appl. No.: 18/671,088

(22) Filed: May 22, 2024

(30) Foreign Application Priority Data
Jun. 1, 2023 (JP) 2023-090978

(51) Int. Cl. G02F 1/1368; G02F 1/1333; G02F 1/1362; H01L 27/12; H01L 29/786

(52) U.S. Cl. CPC G02F 1/1368; G02F 1/133357; G02F 1/136286; H01L 27/1225; H01L 27/1244; H01L 29/7869; G02F 2201/40; G02F 2203/01

(57) ABSTRACT

A display device includes a first conductive layer, a first insulating film arranged on the first conductive layer, an oxide semiconductor layer arranged on the first insulating film, a second conductive layer arranged on the first insulating film and connected to the oxide semiconductor layer, a planarization layer arranged on the oxide semiconductor layer, a first transparent conductive layer in contact with the second conductive layer inside an opening in the planarization layer, and a second transparent conductive layer in contact with the first transparent conductive layer inside the opening.

### CROSS REFERENCE TO RELATED APPLICATIONS

This application claims the benefit of priority to Japanese Patent Application No. 2023-090978, filed on Jun. 1, 2023, the entire contents of which are incorporated herein by reference.

### FIELD

An embodiment of the present invention relates to a display device.

### BACKGROUND

In recent years, the development of a transparent display in which it is possible to visually recognize the background of one surface on the opposite side of another surface is progressing (see Japanese laid-open patent publication No. 2021-092702). The user can visually recognize images, figures, characters, and the like displayed on the transparent display from both sides.

### SUMMARY

A display device according to an embodiment of the present invention includes a first conductive layer, a first insulating film arranged on the first conductive layer, an oxide semiconductor layer arranged on the first insulating film, a second conductive layer arranged on the first insulating film and connected to the oxide semiconductor layer, a planarization layer arranged on the oxide semiconductor layer, a first transparent conductive layer in contact with the second conductive layer inside an opening in the planarization layer, and a second transparent conductive layer in contact with the first transparent conductive layer inside the opening.

### BRIEF DESCRIPTION OF THE DRAWINGS

FIG. 1 is a perspective view illustrating an outline of a display device according to an embodiment of the present invention.

FIG. 2 is a schematic cross-sectional view showing a structure corresponding to A1-A2 of a display device shown in FIG. 1.

FIG. 3 is a plan view illustrating a configuration of a display device according to an embodiment of the present invention.

FIG. 4 is a block diagram showing pixels in a display device according to an embodiment of the present invention.

FIG. 5 is a timing chart of pixels in a display device according to an embodiment of the present invention.

FIG. 6 is a planar layout of pixels in a display device according to an embodiment of the present invention.

FIG. 7 is a cross-sectional view of a pixel in a display device according to an embodiment of the present invention.

FIG. 8 is an enlarged plan view of pixels in a display device according to an embodiment of the present invention.

FIG. 9 is an enlarged plan view of pixels in a display device according to an embodiment of the present invention.

FIG. 10 is an enlarged plan view of pixels in a display device according to an embodiment of the present invention.

FIG. 11 is an enlarged plan view of pixels in a display device according to an embodiment of the present invention.

FIG. 12 is an enlarged plan view of pixels in a display device according to an embodiment of the present invention.

FIG. 13 is a diagram illustrating an aperture ratio of a pixel of a display device according to a comparative embodiment.

FIG. 14 is a diagram illustrating an aperture ratio of a pixel of a display device according to an embodiment of the present invention.

FIG. 15 is a cross-sectional view of a pixel in a display device according to another embodiment of the present invention.

FIG. 16 is an enlarged plan view of pixels in a display device according to another embodiment of the present invention.

FIG. 17 is an enlarged plan view of pixels in a display device according to another embodiment of the present invention.

FIG. 18 is a cross-sectional view of a pixel in a display device according to another embodiment of the present invention.

FIG. 19 is an enlarged plan view of pixels in a display device according to another embodiment of the present invention.

FIG. 20 is an enlarged plan view of pixels in a display device according to another embodiment of the present invention.

FIG. 21 is an enlarged plan view of pixels in a display device according to another embodiment of the present invention.

FIG. 22 is a cross-sectional view of a pixel in a display device according to another embodiment of the present invention.

FIG. 23 is an enlarged plan view of pixels in a display device according to another embodiment of the present invention.

FIG. 24 is an enlarged plan view of pixels in a display device according to another embodiment of the present invention.

FIG. 25 is an enlarged plan view of pixels in a display device according to another embodiment of the present invention.

FIG. 26 is a cross-sectional view of a pixel in a display device according to another embodiment of the present invention.

FIG. 27 is an enlarged plan view of pixels in a display device according to another embodiment of the present invention.

FIG. 28 is an enlarged plan view of pixels in a display device according to another embodiment of the present invention.

FIG. 29 is a cross-sectional view of a pixel in a display device according to another embodiment of the present invention.

FIG. 30 is an enlarged plan view of pixels in a display device according to another embodiment of the present invention.

FIG. 31 is an enlarged plan view of pixels in a display device according to another embodiment of the present invention.

### DESCRIPTION OF EMBODIMENTS

When an aperture ratio of a pixel is low, the transparency decreases, and the display quality of a transparent display deteriorates. For this reason, a transparent display in which the aperture ratio of the pixel is further improved is desirable.

An object of an embodiment of the present invention is to provide a display device having an improved aperture ratio of a pixel.

Hereinafter, embodiments of the present invention will be described with reference to the drawings and the like. However, the present invention can be implemented in various aspects without departing from the gist thereof, and is not to be construed as being limited to the description of the embodiments exemplified below. Further, in order to make the description clearer with respect to the drawings, the width, thickness, shape, and the like of each part may be schematically represented in comparison with actual embodiments, but the schematic drawings are merely examples, and do not limit the interpretation of the present invention. Further, in the present specification and the drawings, the same or similar elements as those described with respect to the above-described drawings are denoted by the same reference signs, and redundant description may be omitted. In this specification and the like, ordinal numbers are given for convenience in order to distinguish parts, portions, and the like, and do not indicate priority or order.

In the present invention, when a single film is processed to form a plurality of films, the plurality of films may have different functions and roles. However, the plurality of films is derived from films formed as the same layer in the same process, and has the same layer structure and the same material. Therefore, the plurality of films is defined as being present in the same layer. Further, when a single film is processed to form a plurality of films, they may be described separately by adding −1, −2, and the like, in the present specification and the like.

In this specification and the like, expressions such as “above” and “below” represent a relative positional relationship between a structure of interest and other structures. In the present specification and the like, in a side view, a direction from a first substrate to a pixel electrode, which will be described later, is defined as “above”, and the opposite direction is defined as “below”. In this specification and claims, the expression “on” in describing the manner of arranging another structure on a certain structure shall include both arranging another structure directly above a certain structure and arranging another structure above a certain structure via yet another structure, unless otherwise specified.

In addition, bottom-gate driving in this specification and the like is such that on/off is controlled by a gate electrode arranged below a semiconductor layer. Further, in this specification and the like, top-gate driving is such that on/off is controlled by a gate electrode arranged above a semiconductor layer. In the present specification, dual-gate driving is such that on/off is controlled by inputting the same control signal to gate electrodes arranged above and below a semiconductor layer.

### First Embodiment

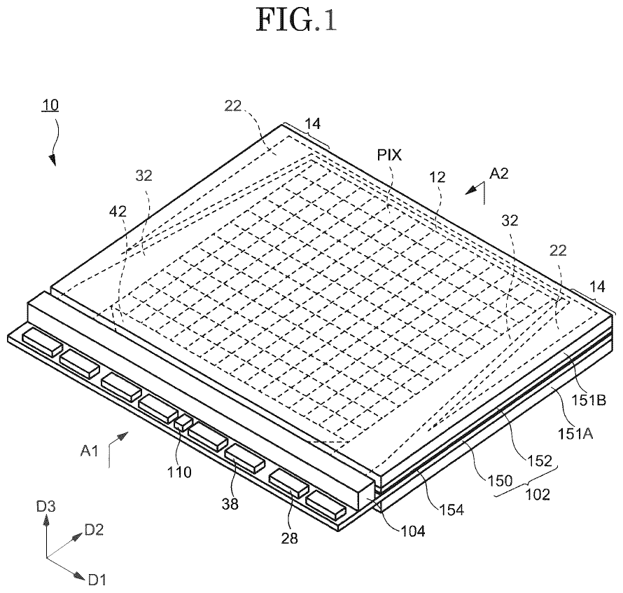

A display device 10 according to an embodiment of the present invention will be described with reference to FIG. 1 to FIG. 14.

### [Outline of Display Device]

FIG. 1 shows a perspective view of the display device 10 according to an embodiment of the present invention. The display device 10 includes a display panel 102, a light source 104, and a first transparent substrate 151A and a second transparent substrate 151B sandwiching the display panel 102. An array substrate 150 (also referred to as a first substrate), a counter substrate 152 (also referred to as a second substrate), a liquid crystal layer (not shown) between the array substrate 150 and the counter substrate 152, a gate drive circuit 28, and a source drive circuit 38 are arranged in the display panel 102. In the following explanation, one direction of a plane of the display panel 102 shown in FIG. 1 is a direction D1, a direction orthogonal to the direction D1 is a direction D2, and a direction orthogonal to a D1-D2 plane is a direction D3.

The array substrate 150 and the counter substrate 152 have light transmittance. The array substrate 150 and the counter substrate 152 are preferably transparent to visible light. The counter substrate 152 is arranged in the direction D3 to face the array substrate 150. The array substrate 150 and the counter substrate 152 are bonded to each other with a sealant 154 while being arranged opposite to each other with a gap therebetween. A liquid crystal layer (not shown) is arranged in the gap between the array substrate 150 and the counter substrate 152.

The display panel 102 has a display region 12 and a peripheral region 14 on the exterior of the display region 12. A plurality of pixels PIX is arranged in a row direction and a column direction in the display region 12. In this case, the row direction refers to a direction parallel to the direction D1, and the column direction refers to a direction parallel to the direction D2. In the display region 12, m pixels are arranged in the row direction, and n pixels are arranged in the column direction. The values of m and n are appropriately set according to the display resolutions in the vertical direction and the horizontal direction. In the display region 12, a gate wiring (also referred to as a scanning signal line) is arranged in the direction D1, and a source wiring (also referred to as a data signal line) is arranged in the direction D2.

The gate drive circuit 28 and the source drive circuit 38 are arranged in the peripheral region 14. FIG. 1 shows an aspect in which the gate drive circuit 28 and the source drive circuit 38 are provided in an integrated circuit (IC) and implemented in a COG (Chip on Glass) method in the array substrate 150. The gate drive circuit 28 and the source drive circuit 38 are not limited to the illustrated aspect. The gate drive circuit 28 and the source drive circuit 38 may be implemented in a COF (Chip on Film) method or may be formed by a thin film transistor (TFT) of the array substrate 150.

A gate wiring region 32, a common wiring region 22, and a source wiring region 42 are arranged in the peripheral region 14. The gate wiring region 32 is a region where a pattern formed by a wiring connecting the gate drive circuit 28 and the gate wiring arranged in the display region 12 is arranged. The common wiring region 22 is a region where a pattern formed by a common wiring is arranged. The common wiring region 22 is used as a wiring for applying a common voltage to a common electrode arranged in the counter substrate 152. The source wiring region 42 is a region where a pattern formed by a wiring connecting the source drive circuit 38 and the data signal line arranged in the display region 12 is arranged. The gate wiring, the common wiring, and the source wiring will be described in detail later.

The light source 104 is arranged along the direction D1. For example, the light source 104 is composed of a light-emitting diode (LED) arranged along the direction D1. The detailed structure of the light source 104 is not limited and may include a light-emitting diode as well as optical members such as a reflector, diffuser, lens, and the like. The light source 104 and a light emission control circuit 110 for controlling the light source 104 may be arranged as a separate member independent of the display panel 102. In addition, a timing of light emission of the light source 104 may be controlled by the light emission control circuit 110 synchronized with the gate drive circuit 28 and the source drive circuit 38. The light emission control circuit 110 for controlling the light source 104 may be arranged as a separate member from the display panel 102 similar to the light source 104, may be mounted on the array substrate 150 as a separate component, or may be incorporated in the gate drive circuit 28 or the source drive circuit 38.

The first transparent substrate 151A and the second transparent substrate 151B are arranged so as to sandwich the display region 12 and the peripheral region 14. The first transparent substrate 151A and the second transparent substrate 151B function as a protective member of the display panel 102. As will be described later, the first transparent substrate 151A and the second transparent substrate 151B function as a light guide plate for introducing light emitted from the light source 104 into the display panel 102.

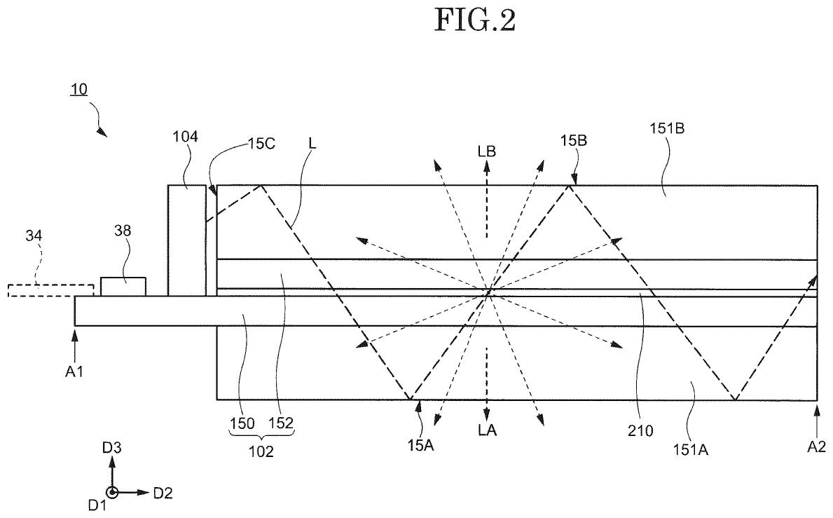

FIG. 2 shows a cross-sectional structure between A1-A2 of the display device 10 shown in FIG. 1. As shown in FIG. 2, the first transparent substrate 151A is arranged on the array substrate 150 side of the display panel 102, and the second transparent substrate 151B is arranged on the counter substrate 152 side. A glass substrate or plastic substrate is used as the first transparent substrate 151A and the second transparent substrate 151B. The first transparent substrate 151A and the second transparent substrate 151B preferably have refractive indices equivalent to those of the array substrate 150 and the counter substrate 152. The array substrate 150 and the first transparent substrate 151A, the counter substrate 152 and the second transparent substrate 151B are bonded to each other by a transparent adhesive (not shown).

The array substrate 150 and the counter substrate 152 face each other with a liquid crystal layer 210 interposed therebetween. Since the array substrate 150 is larger than the counter substrate 152, part of the peripheral region 14 is exposed from the counter substrate 152 in a direction −D2. Drive circuits, such as the source drive circuit 38 are arranged in the array substrate 150. In addition, a flexible printed circuit 34 is attached to the periphery of the array substrate 150.

The light source 104 is arranged adjacent to a side surface of the first transparent substrate 151A or the second transparent substrate 151B. FIG. 2 shows a configuration in which the light source 104 is arranged along one side of the second transparent substrate 151B. Although FIG. 2 shows the configuration in which the light source 104 is attached to the array substrate 150, the configuration is not limited to the configuration in which the light source 104 is arranged, and any configuration may be used as long as the attachment position can be fixed. For example, the light source 104 may be supported by a housing surrounding the display panel 102.

The light source 104 is arranged along a first side surface 15C of the second transparent substrate 151B. The light source 104 irradiates the first side surface 15C of the second transparent substrate 151B with a light L. The light source 104 may also be referred to as a side light source because it emits the light L toward the first side surface 15C. The first side surface 15C of the second transparent substrate 151B facing the light source 104 serves as a light incident surface.

The light L incident from the first side surface 15C of the second transparent substrate 151B propagates in a direction away from the first side surface 15C (direction D2) while being reflected by a first side surface 15B of the second transparent substrate and a first plane 15A of the first transparent substrate 151A. Since the display device 10 is in the atmosphere, the refractive indices of the air, which is a medium of the outside of the first transparent substrate 151A (for example, a direction −D3) and the second transparent substrate 151B (for example, the direction D3), are smaller than the refractive indices of the first transparent substrate 151A and the second transparent substrate 151B. When the light L propagating through the first transparent substrate 151A or the second transparent substrate 151B reaches the first plane 15A or the second plane 15B of the second transparent substrate 151B, the light L is totally reflected when an incident angle is larger than the critical angle. In this way, the totally reflected light L propagates toward the direction D2 while being reflected by the first plane 15A and the second plane 15B.

The liquid crystal layer 210 is formed of a polymer-dispersed liquid crystal. A scattering state and a non-scattering state of the liquid crystal layer 210 are controlled for each pixel PIX (see FIG. 1). At least part of the light L propagating while being reflected by the first plane 15A and the second plane 15B is scattered by the pixel in which the liquid crystal layer 210 is controlled to be in the scattering state. Scattered lights LA and LB having an incident angle smaller than the critical angle are respectively emitted to the outside from the first plane 15A and the second plane 15B. The emitted scattered lights LA and LB are observed by an observer. The array substrate 150, the counter substrate 152, the first transparent substrate 151A, and the second transparent substrate 151B have light transmittance, that is, they are transparent to visible light. Since the liquid crystal layer 210, which is controlled to be in the non-scattering state, is transparent, regions other than the region where the scattered lights LA and LB are emitted are transparent. Therefore, the observer can view the back side through the display panel 102.

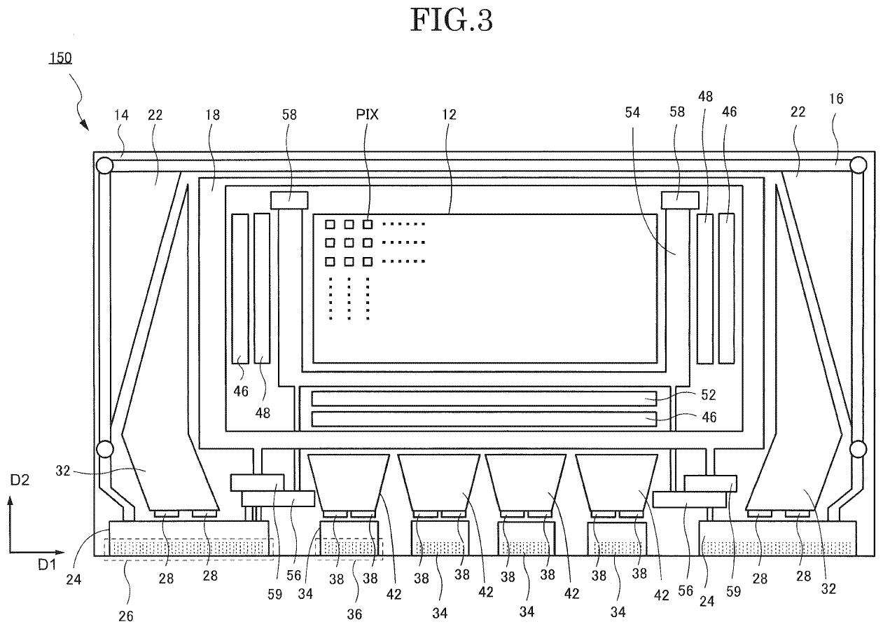

FIG. 3 is a plan view illustrating a configuration of the array substrate 150. As shown in FIG. 3, the array substrate 150 includes the display region 12 and the peripheral region 14.

The display region 12 includes a plurality of pixels PIX arranged in a matrix. Although details will be described later, each of the plurality of pixels PIX includes a plurality of transistors and liquid crystal elements.

The peripheral region 14 is arranged to surround the display region 12. In addition, the peripheral region 14 in the array substrate 150 refers to a region from the display region 12 to an end portion of the array substrate 150. In other words, the peripheral region 14 shall refer to a region (that is, a region external to the display region 12) other than where the display region 12 is arranged on the array substrate 150.

The gate wiring region 32, the source wiring region 42, common wirings 16 and 18, the common wiring region 22, terminal parts 26 and 36, flexible printed circuits 24 and 34, and various test circuits are arranged in the peripheral region 14 in addition to the gate drive circuit 28 and the source drive circuit 38. The terminal parts 26 and 36 are arranged along one side of the array substrate 150.

The flexible printed circuit 24 is connected to the terminal part 26. The flexible printed circuit 24 supplies various signals to the gate drive circuit 28, the common wirings 16 and 18, a protection circuit 59 for ESD, and a QD pad 56. The gate drive circuit 28 is connected to a plurality of gate wirings, and each of the plurality of gate wirings is electrically connected to each of the plurality of pixels PIX in the display region 12. The gate wiring region 32 is a region where the plurality of gate wirings is arranged, and the detailed arrangement of the plurality of gate wirings is not shown in the drawing. The number of gate wirings connected to the two gate drive circuits 28 corresponds to the number of rows of the pixel PIX in the display region 12. Further, although the configuration in which the gate wiring region 32 is arranged away from the display region 12 is shown, the gate wiring and the pixel PIX are actually electrically connected.

The flexible printed circuit 34 is connected to the terminal part 36. The flexible printed circuit 34 supplies a video signal to the source drive circuit 38. The source drive circuit 38 is connected to a plurality of source wirings, and each of the plurality of source wirings is electrically connected to each of the plurality of pixels PIX in the display region 12. The source wiring region 42 is a region where the plurality of source wirings is arranged, and the detailed arrangement of the plurality of source wirings is not shown in the drawing. The number of source wirings connected to the eight source drive circuits 38 shown corresponds to at least three times the number of columns of the pixel PIX in the display region 12. Hereinafter, the case where the number of source wirings is four times the number of columns of the pixel PIX in the display region 12 will be described. Further, although the configuration in which the source wiring region 42 is arranged separately from the display region 12 is shown, the source wiring and the pixel PIX are actually electrically connected.

The common wiring 18, a protection circuit 46 for ESD, a gate test circuit 48, and a test line 54 are arranged between the gate wiring region 32 and the display region 12. The common wiring 18, the protection circuit 46 for ESD, a source test circuit 52, and the test line 54 are arranged between the source wiring region 42 and the display region 12. The test line 54 is connected to a protection circuit 58 for ESD and the QD pad 56. In addition, the common wiring 18 is connected to the protection circuit 59 for ESD.

The common wiring 16 is arranged to surround the peripheral region 14 in the array substrate 150 and is supplied with a signal from two flexible printed circuits 24. The common wiring 16 is electrically connected to the mesh-shaped common wiring region 22.

### [Pixel Circuit]

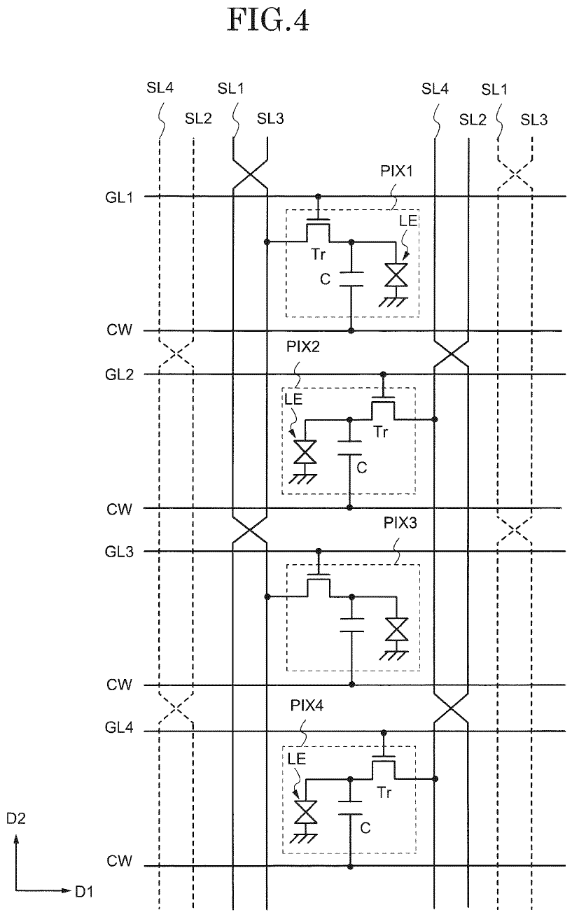

FIG. 4 is a diagram illustrating pixel circuits of pixels PIX1 to PIX4 included in the display device 10 according to an embodiment of the present invention. In the present embodiment, the display device 10 capable of supplying an on-voltage simultaneously to four gate wirings GL1 to GL4 and charging four pixels PIX arranged in the column direction simultaneously by four source wirings SL1 to SL4 will be described. As a result, one horizontal period can be longer than the horizontal period in line order. In other words, it is possible to reduce the time required for scanning all the pixel lines arranged in the display region 12 to ¼. Therefore, in a high-speed drive panel such as a transparent display or a large panel, the charging period of the pixels PIX1 to PIX4 can be sufficiently secured. Hereinafter, a configuration of the pixel according to the present embodiment will be described in detail. Further, in the case where the pixels PIX1 to PIX4 are not distinguished from each other in the following explanation, they are referred to as the pixel PIX. In the case where the gate wirings GL1 to GL4 and the source wirings SL1 to SL4 are not distinguished from each other, they are referred to as the gate wiring GL or the source wiring SL.

The four pixels PIX1 to PIX4 are arranged in the column direction (direction D2). Each of the four pixels PIX1 to PIX4 is electrically connected to each of the four gate wirings GL1 to GL4. Each of the four pixels PIX1 to PIX4 is electrically connected to each of the four wirings SL1 to SL4. Each of the four pixels PIX1 to PIX4 is connected to a capacitive wiring CW.

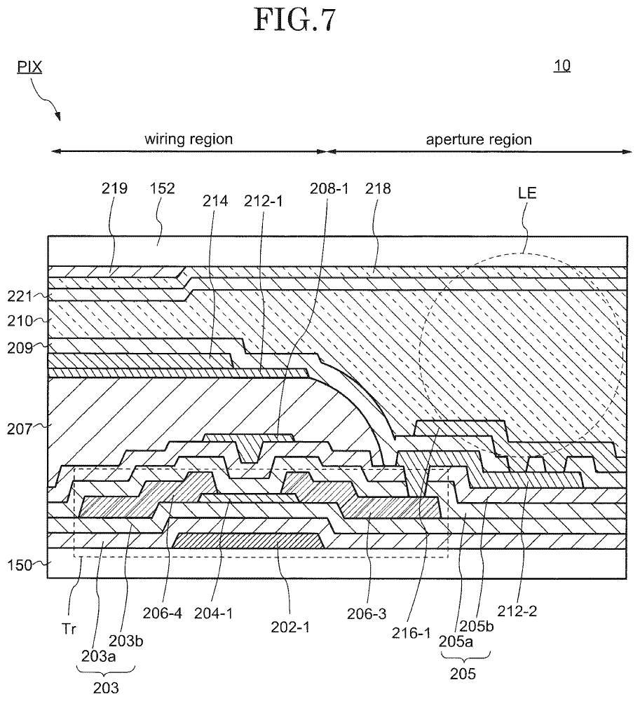

A pixel circuit of each pixel PIX includes a transistor Tr, a liquid crystal element LE, and a storage capacitor C. A gate of the transistor Tr is connected to the gate wiring GL, a source of the transistor Tr is connected to the source wiring SL, and a drain of the transistor Tr is connected to one electrode of the liquid crystal element LE and one electrode of the storage capacitor C. The other electrode of the liquid crystal element LE is connected to a common electrode 218 (see FIG. 7), which will be described later. The other electrode of the storage capacitor C is connected to the capacitive wiring CW.

The transistor Tr has a function of controlling a writing period of the video signal supplied from the source wiring SL to the pixel PIX by switching between the on-state and the off-state. Turning on the transistor Tr makes it possible to write a potential corresponding to the video signal supplied from the source wiring SL to the storage capacitor C electrically connected to the transistor Tr. In addition, turning off the transistor Tr makes it possible to hold the potential held in the storage capacitor C.

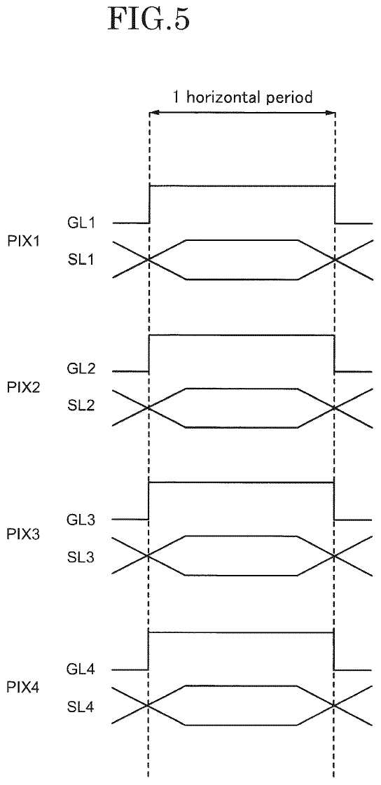

FIG. 5 is a timing chart of the display device 10. Normally, the pixel columns arranged in the direction D2 are sequentially charged with the same source wiring SL by supplying the on-voltage to the gate wiring GL row by row. On the other hand, in the present embodiment, each transistor Tr of the four pixels PIX1 to PIX4 is simultaneously turned on by supplying the on-voltage simultaneously to the four gate wirings GL in one horizontal period. In this state, the video signal is simultaneously supplied to the different source wirings SL1 to SL4. As a result, the four pixels PIX1 to PIX4 arranged in the direction D2 can be simultaneously driven.

### [Planar Layout of Pixel]

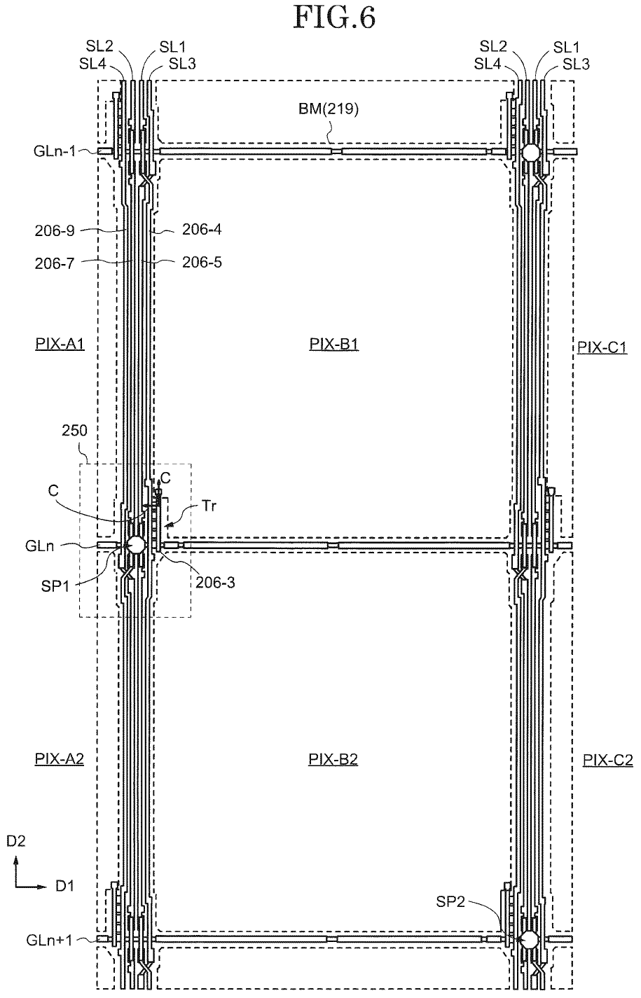

A planar layout of the pixel PIX in the display device 10 according to the first embodiment will be described with reference to FIG. 6. First, FIG. 6 shows a plan view of a configuration of pixels PIX-A1, PIX-A2, PIX-B1, PIX-B2, PIX-C1, and PIX-C2.

As shown in FIG. 6, gate wirings GLn−1 to GLn+1 are arranged along the direction D1. In addition, the source wirings SL1 to SL4 are arranged along the direction D2. In this case, an opening region of the pixel PIX-B1 is a region surrounded by the adjacent gate wiring GLn−1, the gate wiring GLn, the source wiring SL1, and the source wiring SL4. A black matrix BM (a light-shielding layer 219 to be described later) is arranged so as to cover the gate wiring GL, the source wirings SL1 to SL4, and the transistor Tr.

As shown in FIG. 6, the source wiring SL1 and source wiring SL3, and the source wiring SL2 and source wiring SL4 are arranged so as to sandwich one column of pixels PIX-B1 and PIX-B2. In other words, four source wirings SL1 to SL4 are arranged between one column of pixels and another column of pixels.

The transistor Tr is arranged in a region 250 where the gate wiring GL and the source wirings SL1 to SL4 intersect. In addition, the transistor Tr is connected to a pixel electrode. The pixel electrode is arranged in the opening region of the pixel PIX-B1. In addition, a plurality of spacers SP is arranged so as to have regularity with respect to an intersection of the pixel PIX arranged in a matrix. For example, the plurality of spacers may be arranged every other row and every other column of pixels PIX. In other words, the spacer SP may not be arranged at an intersection adjacent to the intersection where the spacer SP is arranged.

In the region 250 where the gate wiring GL and the source wirings SL1 to SL4 shown in FIG. 6 intersect, the source wiring SL2 and the source wiring SL4 are adjacent to the pixel PIX-A1 and the pixel PIX-A2. Further, in the region 250, the source wiring SL1 and the source wiring SL3 are adjacent to the pixel PIX-B1 and the pixel PIX-B2. To describe the position where the spacer SP is arranged, a spacer SP1 overlaps the source wiring SL3 adjacent to the pixel PIX-B1 and the pixel PIX-B2, and the source wiring SL2 adjacent to the pixel PIX-A1 and the pixel PIX-A2. A spacer SP2 overlaps the source wiring SL4 adjacent to the pixel PIX-B2 and a pixel PIX-B3 (not shown), and the source wiring SL3 adjacent to the pixel PIX-C2 and a pixel PIX-C3 (not shown). That is, the spacer SP is arranged on the inner two SLs sandwiched between the outer two SLs of the four SLs adjacent to each other.

Hereinafter, if the source wirings SL1 to SL4 do not need to be distinguished, they are simply referred to as the source wiring SL. In addition, if the gate wirings GLn−1, GLn, and GLn+1 do not need to be distinguished, they are simply referred to as the gate wiring GL.

In the display device, an aperture ratio of a pixel is one of the indicators for evaluating display quality. In a transparent display, since the background of the one surface on the opposite side is visually recognized from another surface, the transparency decreases when the aperture ratio is low. Therefore, it is required to further improve the aperture ratio of the pixel in display device.

The aperture ratio of the pixel in the display device 10 of the present embodiment is improved as compared with the conventional display device.

FIG. 7 is a cross-sectional view along a C-C line in FIG. 6. The C-C line is a bending line segment connecting a line segment perpendicular to the source wiring SL and crossing an oxide semiconductor layer, and a line segment parallel to the source wiring SL and extending from the transistor Tr to the opening region of the pixel PIX. Hereinafter, unless otherwise specified, the cross-sectional view refers to the case where the region 250 is cut like the CC part in FIG. 6. The stacking order of the layers when the display device 10 is viewed in a cross-section will be described in FIG. 7.

As shown in FIG. 7, in the wiring region, a conductive layer 202-1 is arranged on the array substrate 150. A gate insulating film 203 is arranged on the conductive layer 202-1. An oxide semiconductor layer 204-1 is arranged on the gate insulating film 203. The oxide semiconductor layer 204-1 is arranged to face the conductive layer 202-1 via the gate insulating film 203. Conductive layers 206-3 and 206-4 are arranged on the oxide semiconductor layer 204-1. The conductive layers 206-3 and 206-4 are arranged on the gate insulating film 203 and connected to the oxide semiconductor layer 204-1. An insulating film 205 is arranged on the conductive layers 206-3 and 206-4. A conductive layer 208-1 is arranged on the insulating film 205.

The conductive layer 202-1 functions as the gate wiring GL (gate electrode). The conductive layer 206-3 functions as a drain electrode, and the conductive layer 206-4 functions as a source wiring SL (source electrode). The conductive layer 208-1 is connected to the gate wiring GL and functions as a back gate. The conductive layer 202-1, the oxide semiconductor layer 204-1, the insulating film 205, and the conductive layers 206-3 and 206-4 function as the transistor Tr. In addition, although the transistor Tr is described as a bottom-gate-driven transistor in the present embodiment, the present invention is not limited to this, and may be a top-gate-driven transistor or a dual-gate-driven transistor.

The gate insulating film 203 has a stacked nitride insulating film 203a and oxide insulating film 203b. The insulating film 205 includes a stacked oxide insulating film 205a and nitride insulating film 205b. In addition, the oxide semiconductor layer 204-1 is sandwiched between the gate insulating film 203 and the insulating film 205, in particular between the oxide insulating film 203b and the oxide insulating film 205a. Since the oxide insulating film 205a and the oxide insulating film 203b contain oxygen, the oxygen content of the oxide semiconductor layer 204-1 is maintained even after processes for layers above the oxide semiconductor layer 204-1 are performed.

A planarization film 207 is arranged on the conductive layer 208-1, the oxide semiconductor layer 204-1, and the insulating film 205. The planarization film 207 is arranged to alleviate irregularities of various wirings constituting the transistor Tr. In the pixel PIX of the transparent display, the planarization film 207 is preferably removed in the opening region of the pixel PIX. As a result, it is possible to suppress the planarization film 207 from absorbing light in the opening region. Therefore, the planarization film 207 is arranged at a position overlapping the gate wirings GLn−1 to GLn+1 and the source wirings SL1 to SL4 (see FIG. 6). The planarization film 207 is arranged in a region overlapping the conductive layer 206-4 and the transistor Tr. In addition, the planarization film 207 is removed in the opening region of the pixel PIX, so that the planarization film 207 is not arranged between the conductive layer 206-3 and a pixel electrode 216-1. Hereinafter, the opening region may be referred to as an opening of the planarization film 207.

A transparent conductive layer 212-1 is arranged on the planarization film 207. A conductive layer 214 is arranged in contact with the transparent conductive layer 212-1. The transparent conductive layer 212-1 and the conductive layer 214 function as the capacitive wiring CW (see FIG. 4). The transparent conductive layer 212-1 and the conductive layer 214 are arranged at positions overlapping the gate wirings GLn−1 to GLn+1 (see FIG. 6) and the source wirings SL1 to SL4 (see FIG. 6). In addition, the conductive layer 214 also functions as a light-shielding layer. In the present embodiment, although a configuration in which the conductive layer 214 is arranged on the transparent conductive layer 212-1 is described, a configuration in which the transparent conductive layer 212-1 is arranged on the conductive layer 214 may be used. An insulating film 209 is arranged on the conductive layer 214. The insulating film 209 is arranged on the planarization film 207.

Since the planarization film 207 is removed in the opening region, the insulating film 209 is in contact with the insulating film 205. A transparent conductive layer 212-2 is arranged on the insulating film 205. The insulating film 209 is arranged on the transparent conductive layer 212-2. The transparent conductive layer 212-2 is in contact with the insulating film 209. The pixel electrode 216-1 is arranged on the insulating film 209. The pixel electrode 216-1 is in contact with the transparent conductive layer 212-2 via a contact hole arranged in the insulating film 209 in the opening region. The transparent conductive layer 212-2 is in contact with the conductive layer 206-3 via a contact hole arranged in the insulating film 205 in the opening region.

Although not described in detail, in a cross-sectional view at a position other than FIG. 7, an end portion of the transparent conductive layer 212-1 extends between an end portion of the conductive layer 214 and the pixel electrode 216-1. More specifically, the end portion of the transparent conductive layer 212-1 is positioned at a taper of the planarization film 207, and an end portion of the pixel electrode 216-1 also extends to the taper of the planarization film 207. Then, the capacitance C is formed since the transparent conductive layer 212-1 and the pixel electrode 216-1 are facing each other with the insulating film 209 interposed therebetween at the tapered portion of the planarization film 207.

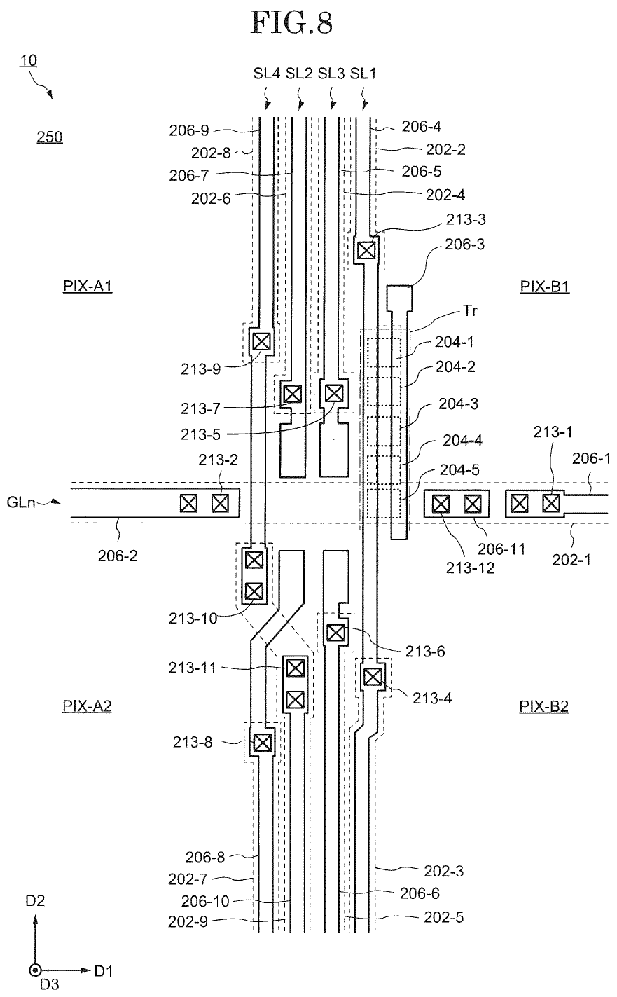

The counter substrate 152 is arranged so as to face the array substrate 150 with each layer interposed therebetween. The light-shielding layer 219, the common electrode 218, and an insulating film 221 are arranged in the counter substrate 152. The light-shielding layer 219 functions as a black matrix BM (see FIG. 6). The light-shielding layer 219 of the structure shown in FIG. 7 is arranged in a region overlapping the conductive layer 206-4 in FIG. 8. The light-shielding layer 219 is arranged in a lattice pattern so as to cover the gate wirings GLn−1 to GLn+1 and the source wiring SL1 to the source wiring SL4. The common electrode 218 has a size that extends over the entire surface of the display region 12 (see FIG. 3). The light-shielding layer 219 may be formed of a metal film, and is arranged in contact with the common electrode 218 formed of a transparent conductive film, thereby functioning as an auxiliary electrode. The liquid crystal layer 210 is arranged between the array substrate 150 and the counter substrate 152 and is sealed with the sealant 154 (see FIG. 1). The pixel electrode 216-1, the liquid crystal layer 210, and the common electrode 218 constitute the liquid crystal element LE.

Next, the region 250 where the gate wiring GLn and the source wirings SL1 to SL4 shown in FIG. 6 intersect will be described with reference to FIG. 8 to FIG. 12.

FIG. 8 is a planar layout of the conductive layers 202-1 to 202-9, the oxide semiconductor layers 204-1 to 204-5, and conductive layers 206-1 to 206-11 in the region 250. The conductive layers 202-1 to 202-9 are arranged on the array substrate 150 (see FIG. 7). The conductive layer 202-1 has a region extending in the direction D1 (also referred to as a first region) and a region that intersects the first region in the direction D2 (also referred to as a second region). The region intersecting in the direction D2 extends to a region where the pixel PIX-B1 is arranged. That is, the gate wiring GL may have an L-shaped pattern. In addition, the conductive layers 202-2 to 202-9 extend in the direction D2. The oxide semiconductor layers 204-1 to 204-5 are arranged on a region of the conductive layer 202-1 intersecting the direction D2 via the gate insulating film 203 (see FIG. 7). An example in which the transistor Tr includes five oxide semiconductor layers 204-1 to 204-5 is shown in the present embodiment. The oxide semiconductor layers 204-1 to 204-5 are arranged side by side in the direction D2. The oxide semiconductor layer 204-5 is arranged in a region overlapping an intersection of the regions of the conductive layer 202-1 extending in the direction D1 and extending in the direction D2. Since the oxide semiconductor layers 204-1 to 204-5 are divided into a plurality of regions, the effect of heat generation can be reduced as compared with the case where the layers are arranged as one consecutive region. The number of divisions is not particularly limited. Light that has been guided through the glass substrate (the array substrate 150 shown in FIG. 7) from the conductive layer 202-1 side toward the oxide semiconductor layers 204-1 to 204-5 is reflected by the conductive layer 202-1. Therefore, the oxide semiconductor layers 204-1 to 204-5 arranged above the conductive layer 202-1 are less likely to be degraded by light. The conductive layers 206-1 to 206-11 are arranged on the gate insulating film and the oxide semiconductor layers 204-1 to 204-5. The conductive layers 206-1, 206-2, and 206-11 extend in the direction D1 and the conductive layers 206-3 to 206-10 extend in the direction D2.

The conductive layer 202-1 overlaps the conductive layers 206-1, 206-2, and 206-11. The conductive layer 202-1 is connected to the conductive layer 206-1 via a contact hole 213-1 arranged in the gate insulating film 203 (see FIG. 7), and is connected to the conductive layer 206-2 via a contact hole 213-2 arranged in the gate insulating film 203. A region of the conductive layer 202-1 extending in the direction D1 functions as a gate wiring. In addition, a region of the conductive layer 202-1 extending in the direction D2 functions as a gate electrode.

The conductive layers 202-2 and 202-3 overlap the conductive layer 206-4. The conductive layer 202-2 is connected to the conductive layer 206-4 via a contact hole 213-3 arranged in the gate insulating film 203 (see FIG. 7). The conductive layer 202-3 is connected to the conductive layer 206-4 via a contact hole 213-4 arranged in the gate insulating film 203 (see FIG. 7). The conductive layer 206-4 intersects the conductive layer 202-1. The conductive layer 206-4 functions as the first source wiring SL1. Further, a region of the conductive layer 206-4 that does not overlap the conductive layers 202-2 and 202-3 functions as a source electrode of the transistor Tr. The conductive layer 206-3 functions as a drain electrode of the transistor Tr. The conductive layer 206-3 is arranged along a region extending in the direction D2 of the conductive layer 202-1. A region where the conductive layer 206-3 extends in the direction D2 is a region connected to the oxide semiconductor layers 204-1 to 204-5 and the transparent conductive layer 212-2 (see FIG. 7).

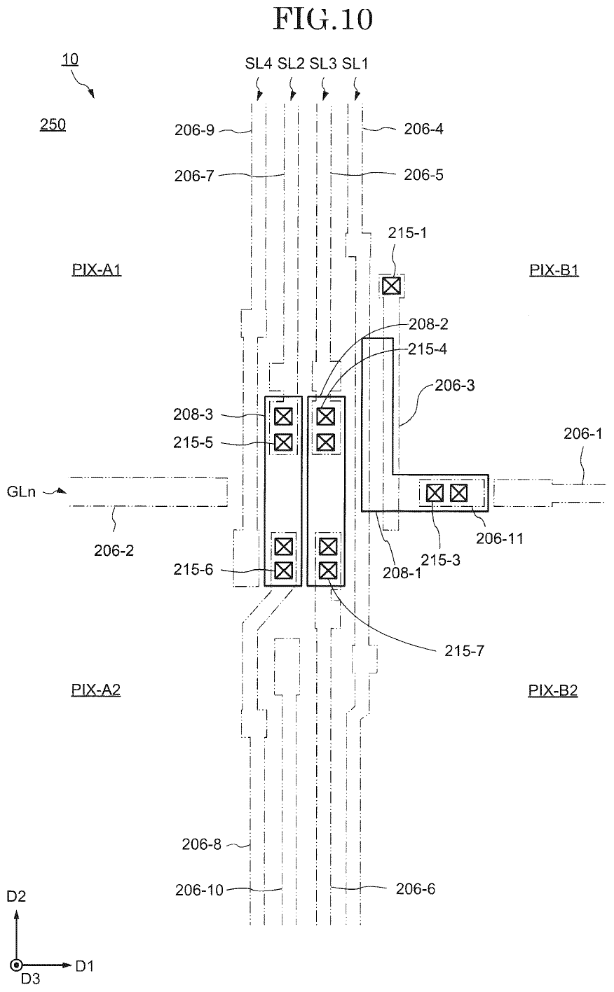

The conductive layer 202-4 overlaps the conductive layer 206-5 and is connected to the conductive layer 206-5 via a contact hole 213-5 arranged in the gate insulating film 203. The conductive layer 202-5 overlaps the conductive layer 206-6 and is connected to the conductive layer 206-6 via a contact hole 213-6 arranged in the gate insulating film 203. The conductive layer 206-5 is connected to the conductive layer 206-6 via a conductive layer 208-2 (see FIG. 10) described later. As a result, the conductive layer 206-5, the conductive layer 206-6, and the conductive layer 208-2 function as the third source wiring SL3.

The conductive layer 202-6 overlaps the conductive layer 206-7 and is connected to the conductive layer 206-7 via a contact hole 213-7 arranged in the gate insulating film 203 (see FIG. 7). The conductive layer 202-7 overlaps the conductive layer 206-8 and is connected to the conductive layer 206-8 via a contact hole 213-8 arranged in the gate insulating film 203. The conductive layer 206-7 is connected to the conductive layer 206-8 via a conductive layer 208-3 (see FIG. 10). The conductive layer 206-7, the conductive layer 206-8, and the conductive layer 208-3 function as the second source wiring SL2.

The conductive layer 202-8 overlaps the conductive layer 206-9 and is connected to the conductive layer 206-9 via a contact hole 213-9 arranged in the gate insulating film 203. The conductive layer 202-9 overlaps the conductive layer 206-9 and the conductive layer 206-10. The conductive layer 202-9 is connected to the conductive layer 206-9 via a contact hole 213-10 arranged in the gate insulating film 203 (see FIG. 7). The conductive layer 202-9 is connected to the conductive layer 206-10 via a contact hole 213-11 arranged in the gate insulating film 203. The conductive layer 206-9 has a region that intersects the conductive layer 202-1. The conductive layer 206-9 and the conductive layer 206-10 function as the fourth source wiring SL4.

In addition, the conductive layer 202-1 overlaps the conductive layer 206-11 and is connected to the conductive layer 206-11 via a contact hole 213-12 arranged in the gate insulating film 203 (see FIG. 7). The conductive layer 202-9 has a region that overlaps and intersects the conductive layer 206-8. That is, there is a region where the second source wiring SL2 intersects the fourth source wiring SL4. Although not described in detail, the first source wiring SL1 has a region that intersects the third source wiring SL3, as shown in FIG. 6.

As shown in FIG. 8, the gate wiring GLn is configured by stacking the conductive layer 202-1 and the conductive layers 206-1 and 206-2. The conductive layer 202-1 extends along the direction D1. In addition, for the gate wiring GL, in the region intersecting the source wiring SL1 to the source wiring SL4, only the conductive layer 202-1 is arranged and is spaced apart from the conductive layer 206-1 and the conductive layer 206-2. In addition, the source wiring SL1 is configured by stacking the conductive layers 202-2 and 202-3 and the conductive layer 206-4. Further, for the gate wiring GL, in the region intersecting the source wiring SL1, only the conductive layer 206-4 is arranged and is spaced apart from the conductive layer 202-2 and the conductive layer 202-3. As a result, even if static electricity is generated in the manufacturing process of the display region 12 and the peripheral region 14 in the array substrate 150 shown in FIG. 3, the static electricity can be released, so that it is possible to suppress the generation of defects caused by static electricity.

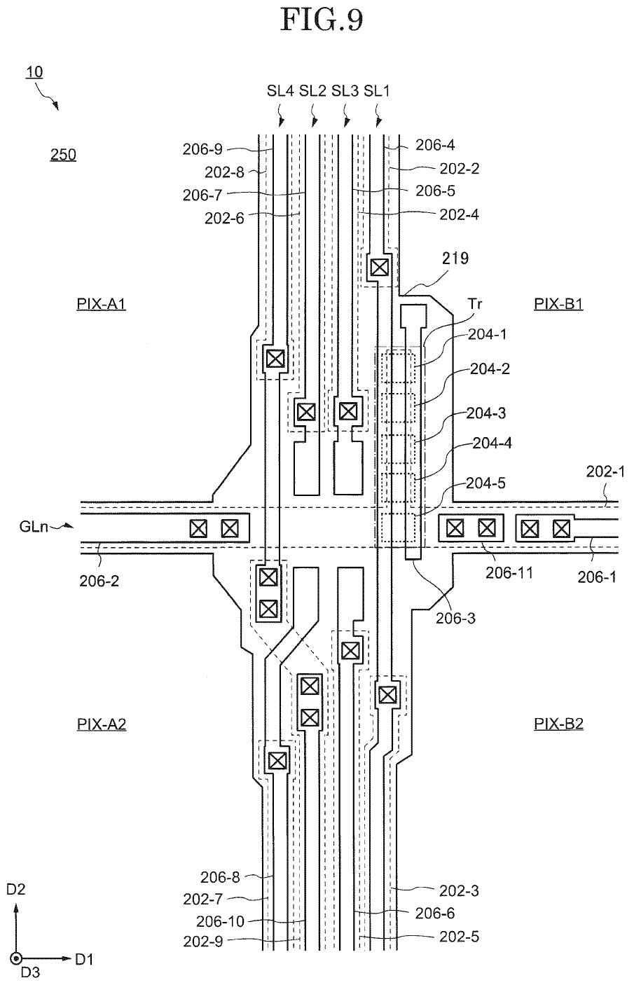

FIG. 9 is a planar layout of the conductive layers 202-1 to 202-9, the oxide semiconductor layers 204-1 to 204-5, the conductive layers 206-1 to 206-11, and the light-shielding layer 219 in the region 250. The light-shielding layer 219 arranged in the counter substrate 152 (see FIG. 7) is arranged in a lattice pattern so as to cover the conductive layers 202-1 to 202-9, the oxide semiconductor layers 204-1 to 204-5, and the conductive layers 206-1 to 206-11. The light-shielding layer 219 covers a region extending in the direction D1 of the conductive layer 202-1, a region arranged to intersect in the direction D2, and the conductive layer 206-3. In addition, an area of the opening arranged in the light-shielding layer 219 defines the aperture ratio of the pixel PIX. The relationship between the transistor Tr and the aperture ratio will be described later.

FIG. 10 is a planar layout of the conductive layers 206-1 to 206-11 and the conductive layers 208-1 to 208-3 in the region 250. The conductive layers 206-1 to 206-11 are as described in FIG. 8. The conductive layers 208-1 to 208-3 are arranged on the insulating film 205 (see FIG. 7). The conductive layer 208-1 has a region (also referred to as a third region) extending in the direction D1 and a region (also referred to as a fourth region) extending in the direction D2. The region extending in the direction D2 overlaps the region extending in the direction D2 (also referred to as the second region) in the oxide semiconductor layers 204-1 to 204-5 and the conductive layer 202-1 (see FIG. 9). In addition, the conductive layer 208-1 in the region extending in the direction D1 overlaps the conductive layer 206-11 and is connected to the conductive layer 206-11 via a contact hole 215-3 arranged in the insulating film 205 (see FIG. 7). As a result, the scanning signal supplied to the gate wiring GL is supplied to the conductive layer 208-1. That is, the conductive layer 208-1 functions as the back gate of the transistor Tr. Although the transistor Tr of the display device according to the present invention includes the back gate, the transistor Tr may not include the back gate. The conductive layer 208-2 extends in the direction D2. The conductive layer 208-2 overlaps the conductive layer 206-5 and the conductive layer 206-6, and is connected to the conductive layer 206-5 and the conductive layer 206-6 via contact holes 215-4 and 215-7 arranged in the insulating film 205 (see FIG. 7). The conductive layer 208-3 extends in the direction D2. The conductive layer 208-3 overlaps the conductive layer 206-7 and the conductive layer 206-8, and is connected to the conductive layer 206-7 and the conductive layer 206-8 via contact holes 215-5 and 215-6 arranged in the insulating film 205 (see FIG. 7).

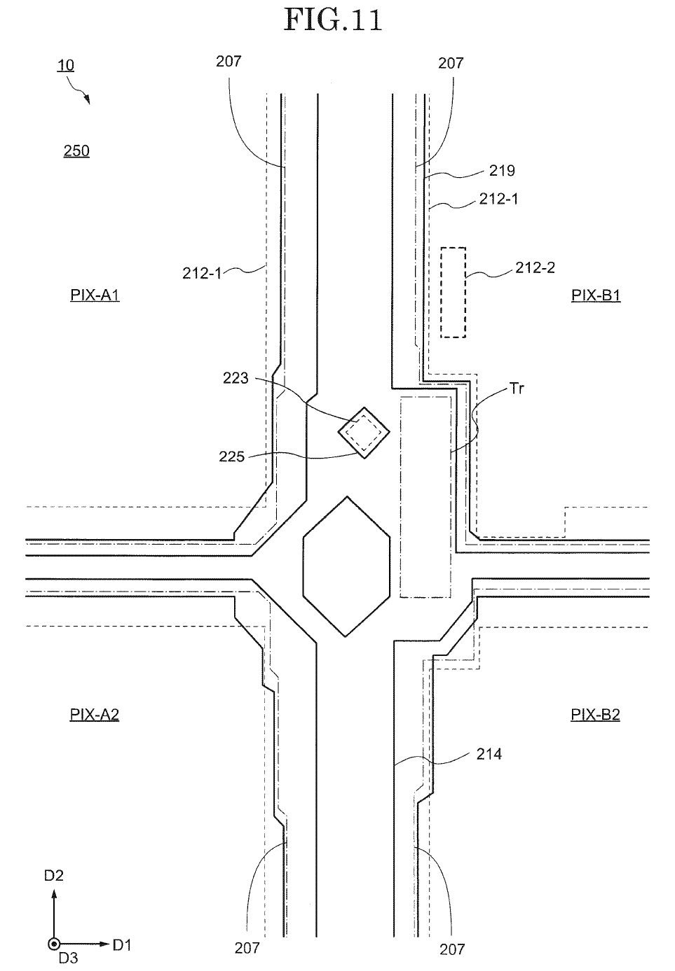

FIG. 11 is a planar layout of the planarization film 207, the transparent conductive layers 212-1 and 212-2, the conductive layer 214, and the light-shielding layer 219 in the region 250. As shown in FIG. 11, the planarization film 207 is removed in the opening region of the pixels PIX-A1, PIX-A2, PIX-B1, and PIX-B2. That is, the planarization film 207 is not arranged in the opening region, but is arranged on the wiring region. The transparent conductive layer 212-1 is arranged on the planarization film 207. In addition, the conductive layer 214 is arranged on the transparent conductive layer 212-1. The transparent conductive layer 212-1 and the conductive layer 214 function as the capacitive wiring CW (see FIG. 4). The transparent conductive layer 212-1 is arranged on the conductive layers 206-1 to 206-11 (see FIG. 10) via the planarization film 207. Since the source wirings SL1 to SL4 and the capacitive wiring CW (see FIG. 4) are arranged apart from each other, the source wirings SL1 to SL4 are not easily affected by the potential of the capacitive wiring CW. In addition, an electric resistance of the conductive layer 214 formed of the conductive material described later is smaller than an electric resistance of the transparent conductive layer 212-1. The influence of a change in the potential of the capacitive wiring CW (see FIG. 4) differs depending on the position of the pixel PIX. However, since the electric resistance of the conductive layer 214 is relatively low, variations in the way the electric potential converges are less likely to occur. In addition, the transparent conductive layer 212-1 has an opening 223 and the conductive layer 214 has an opening 225. The opening 223 and the opening 225 are arranged so as to overlap each other. The openings 223 and 225 are arranged at positions not overlapping the transistor Tr. Moisture contained in the planarization film 207 can be released via the openings 223 and 225.

The transparent conductive layer 212-1 and the conductive layer 214 are arranged in a lattice pattern so as to cover the gate wiring GL and the source wirings SL1 to SL4. The storage capacitor C (see FIG. 4) is adjusted according to the size of the region without the transparent conductive layer 212-1. In addition, the conductive layer 214 is arranged so as to cover the transistor Tr. As a result, degradation of the transistor Tr due to light can be suppressed.

Although the example in which the conductive layer 214 is arranged above the transparent conductive layer 212-1 is shown, the conductive layer 214 may be arranged below the transparent conductive layer 212-1. The conductive layer 214 may be stacked with the transparent conductive layer 212-1. The conductive layer 214 has a light-shielding effect. Therefore, the conductive layer 214 can block the reflected light from the source wirings SL1 to SL4 (see FIG. 10) and the gate wiring GL (see FIG. 10) arranged in the wiring region. The conductive layer 214 is arranged so as to have a width smaller than a combined width of the source wirings SL1 to SL4 (see FIG. 10) in a plan view. In addition, the conductive layer 214 is arranged so as to have a width similar to a width of the gate wiring GL (see FIG. 10), but the width may be smaller than the width of the gate wiring GL. Therefore, it is possible to suppress the display panel 102 from emitting the reflected light reflected at the edge of the source wiring SL. In addition, the width of the conductive layer 214 or the combined width of the source wirings SL1 to SL4 refers to a length in a direction (direction D1) intersecting the direction in which the source wirings SL1 to SL4 extend. In addition, the width of the gate wiring GL refers to a length in a direction (direction D2) intersecting the direction in which the gate wiring GL extends. The transparent conductive layer 212-2 extends in the direction D2 away from the transparent conductive layer 212-1.

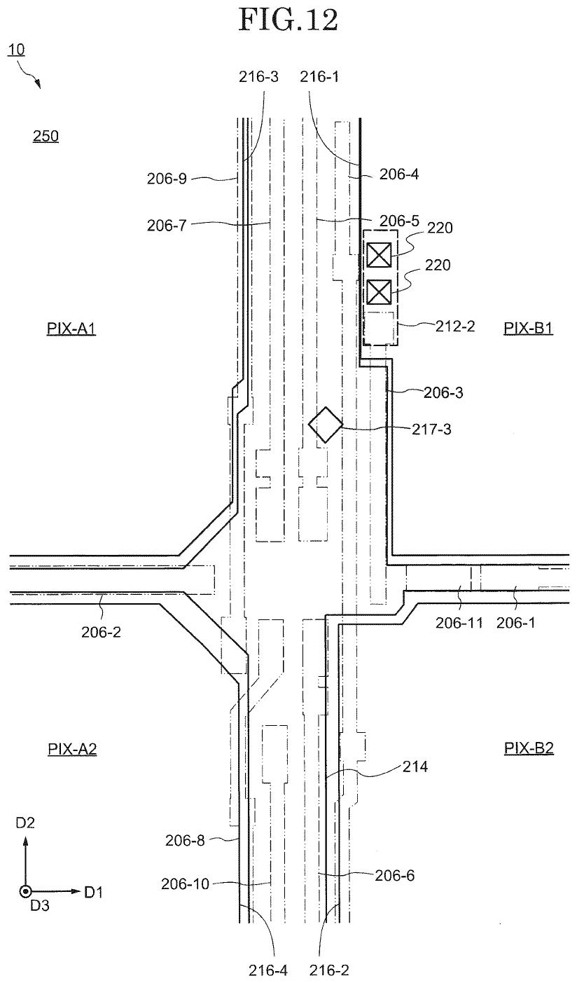

FIG. 12 is a planar layout of the conductive layers 206-1 to 206-11, the conductive layer 214, the pixel electrodes 216-1 to 216-4, and the transparent conductive layer 212-2 in the region 250. The conductive layers 206-1 to 206-11 are as described in FIG. 8. The conductive layer 214 is as described in FIG. 11. The pixel electrodes 216-1 to 216-4 are arranged on the insulating film 209. The pixel electrodes 216-1 to 216-4 are arranged in the opening region of the pixel PIX. The pixel electrode 216-1 covers the transparent conductive layer 212-2. The pixel electrode 216-1 is connected to the transparent conductive layer 212-2 via a contact hole 220 arranged in the insulating film 209 (see FIG. 7).

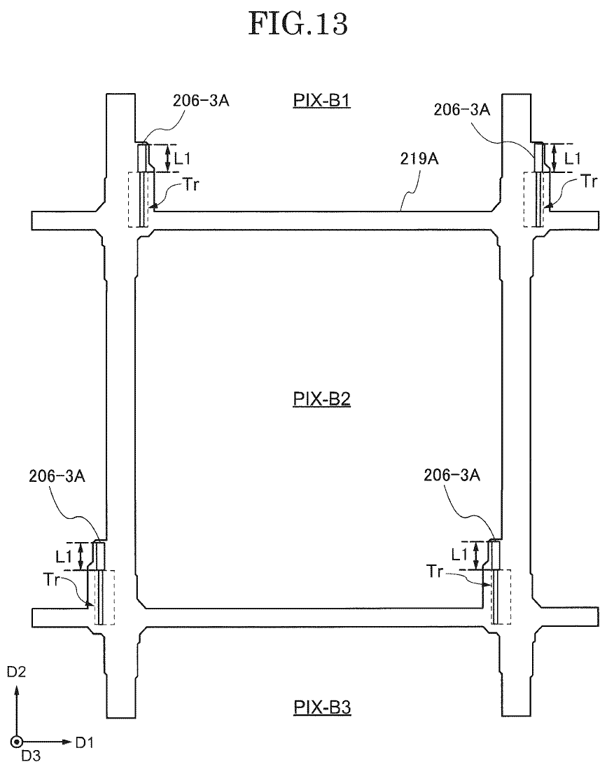

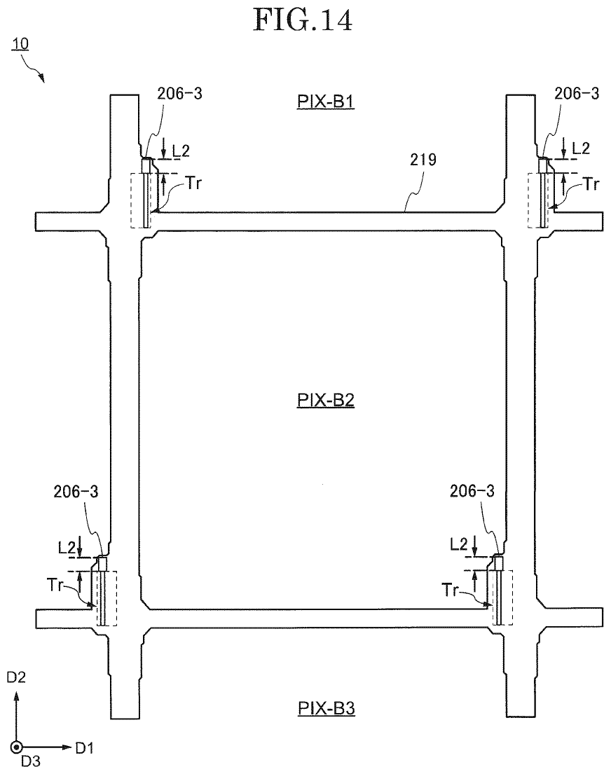

Next, the aperture ratio of the display device 10 will be described with reference to FIG. 13 and FIG. 14. FIG. 13 is a diagram illustrating an aperture ratio of a pixel of a display device of a comparative example. FIG. 14 is a diagram illustrating the aperture ratio of the pixel of the display device 10 according to an embodiment of the present invention.

FIG. 13 shows a light-shielding layer 219A covering the gate wiring GL, the source wirings SL1 to SL4 (see FIG. 9), and the transistor Tr. The gate wiring GL and the source wirings SL1 to SL4 (see FIG. 9) are arranged in the same manner as the display device 10 for comparison. A length of a region of a conductive layer 206-3A extending in the direction D2 from the transistor Tr refers to L1.

FIG. 14 shows the light-shielding layer 219 covering the gate wiring GL, the source wirings SL1 to SL4 (see FIG. 9), and the transistor Tr. A length of a region of the conductive layer 206-3 extending in the direction D2 from the transistor Tr refers to L2.

As shown in FIG. 13, in the comparative display device, the conductive layer 206-3A extends in the direction D2 from the transistor Tr over a relatively long distance L1. In contrast, as shown in FIG. 14, a distance in which the conductive layer 206-3 extends in the direction D2 from the transistor Tr is L2 which is shorter than L1. In addition, in the display device of the comparative example, the pixel electrode 216-1 (see FIG. 7) and the conductive layer 206-3A were electrically connected via a metal conductive layer covered by the light-shielding layer 219. A relatively wide range of light shielding was required to cover the metal conductive layer. On the other hand, according to the display device 10 of the present application, part of the conductive layer 206-3 can be replaced with the transparent conductive layer 212-2 (see FIG. 7) in the pixel PIX-B2. In addition, the transparent conductive layer 212-2 is transparent and does not need to be covered with the light-shielding layer 219A and shielded from light. Therefore, in the display device 10, an area of the conductive layer 206-3 covering the light-shielding layer 219 is smaller than an area of the conductive layer 206-3A covering the light-shielding layer 219A in the comparative example. The same applies to other pixels such as the pixels PIX-B1 and PIX-B3. As described above, according to the display device 10, the aperture ratio can be increased as compared with the display device of the comparative embodiment. In addition, the appearance at the intersection of the gate wiring GL covered with the light-shielding layer 219 and the source wirings SL1 to SL4 (see FIG. 6) can be improved.

In addition, the planarization film 207 forms a large step near the border between the wiring region and the opening region, as shown in FIG. 7. Therefore, in the step of forming the transparent conductive layer 212-1, a photoresist cannot be removed due to the step, and the residue of the transparent conductive layer 212-1 tends to remain in an unwanted part such as the vicinity of the bottom of the step. Conventionally, since the contact hole connecting the conductive layer 206-3 and the pixel electrode 216-1 is close to the step, the residue of the transparent conductive layer 212-1 that has not been removed may be short-circuited by contacting the pixel electrode 216-1 or the like in the opening region. However, since the transparent conductive layer 212-2 is transparent in the present embodiment, the aperture ratio is not reduced even if the contact portion between the transparent conductive layer 212-2 and the pixel electrode 216-1 is arranged at a position away from the wiring region. Therefore, according to the display device 10, the contact portion between the transparent conductive layer 212-2 and the pixel electrode 216-1 can be arranged separately from the wiring region so as not to reach the residue of the transparent conductive layer 212-1, and it is less likely that short circuits occur.

### Second Embodiment

In the display device 10 described in the first embodiment, although the pixel electrode is connected via the transparent conductive layer to the drain of the transistor Tr, the method for connecting the pixel electrode to the drain of the transistor Tr is not limited to the method described above. A pixel electrode of a display device 310 according to the second embodiment is connected to the drain electrode of the transistor Tr via the oxide semiconductor layer. Hereinafter, parts other than the display device 10 will be mainly described.

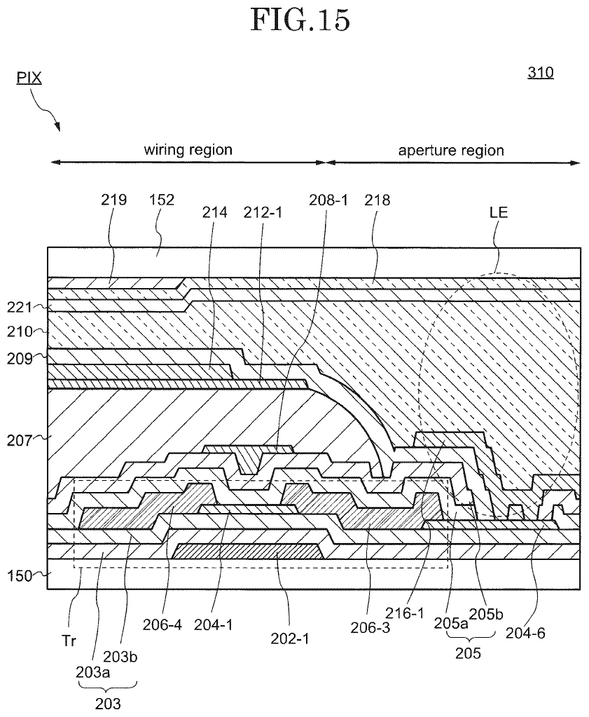

FIG. 15 is a cross-sectional view in the display device 310. The stacking order of the layers when the display device 310 is viewed in a cross-section will be described in FIG. 15.

As shown in FIG. 15, an oxide semiconductor layer 204-6 is arranged on the gate insulating film 203 in the opening region. The insulating film 209 is arranged on the oxide semiconductor layer 204-6 in the opening region. The pixel electrode 216-1 is arranged on the insulating film 209. The pixel electrode 216-1 is connected to the oxide semiconductor layer 204-6 via the contact holes arranged in the insulating films 205 and 209. The oxide semiconductor layer 204-6 is in contact with the conductive layer 206-3 in the opening region. The pixel electrode 216-1 is arranged in the opening region of the pixel PIX. The pixel electrode 216-1 does not cover the source wiring SL and the transistor Tr, but covers part of the oxide semiconductor layer 204-6 and the conductive layer 206-3.

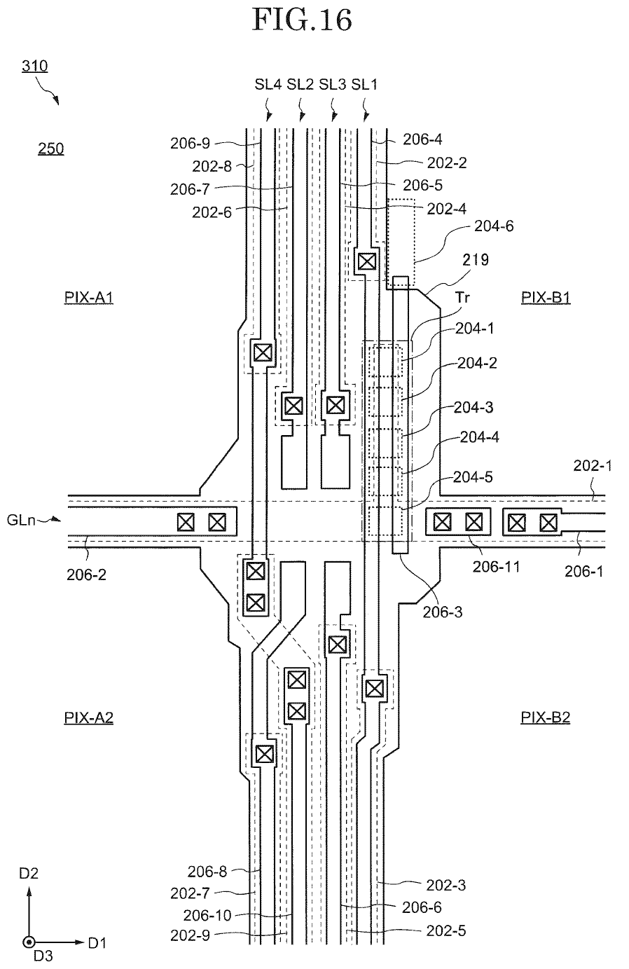

FIG. 16 is a planar layout of the conductive layers 202-1 to 202-9, the oxide semiconductor layers 204-1 to 204-6, the conductive layers 206-1 to 206-11, and the light-shielding layer 219 in the region 250. As shown in FIG. 16, the oxide semiconductor layers 204-1 to 204-6 are not in direct contact with each other. The conductive layer 206-3 extending in the direction D2 is arranged on the oxide semiconductor layers 204-1 to 204-6.

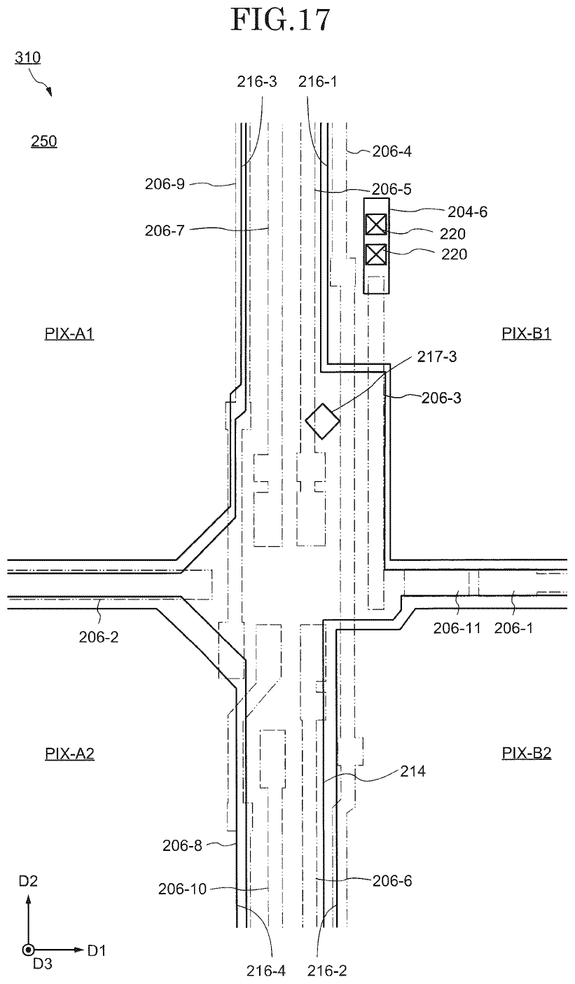

FIG. 17 is a planar layout of the oxide semiconductor layer 204-6, the conductive layers 206-1 to 206-11, the conductive layer 214, and the pixel electrodes 216-1 to 216-4 in the region 250. As shown in FIG. 17, the pixel electrode 216-1 covers the oxide semiconductor layer 204-6. The pixel electrode 216-1 and the oxide semiconductor layer 204-6 are connected via the contact hole 220 arranged in the insulating film 209 (see FIG. 15). Since the oxide semiconductor layer 204-6 has light transmittance, even when the conductive layer 206-3 and the pixel electrode 216-1 are connected via the oxide semiconductor layer 204-6 arranged in the opening region, light is not shielded, and the aperture ratio does not decrease.

The oxide semiconductor layer 204-6 of the display device 310 is in contact with the insulating film 209. The oxide semiconductor layer 204-6 is supplied with hydrogen from the insulating film 209 during the process and reduced. Since the oxide semiconductor layer 204-6 approaches n-type, the electric resistance decreases and has conductive properties. In this way, the resistance of the oxide semiconductor layer 204-6 in contact with the insulating film 209 is reduced and becomes an oxide conductive layer. In the present specification, the term “oxide conductive layer” refers to an oxide semiconductor having conductive properties by reducing the resistance of the oxide semiconductor layer.

In the present embodiment, a material containing a crystal structure is preferably used as the oxide semiconductor layer 204-6. In the structure of the present embodiment, in the step of etching the transparent conductive layer 212-1, the oxide semiconductor layer 204-6 may be exposed when the transparent conductive layer 212-1 is etched. In this case, if the oxide semiconductor layer 204-6 is composed of a material containing a crystal structure, it is less likely to be etched and disappear. Therefore, it is possible to maintain a designed pattern easily without protecting the oxide semiconductor layer 204-6 with a protective layer.

### Third Embodiment

The transistor Tr of the display devices 10 and 310 has a back gate (the conductive layer 208-1 shown in FIG. 15), but the transistor Tr of the display device according to the present invention does not have to have a back gate. A display device 410 according to the third embodiment does not include a back gate. Parts different from the display device 310 of the second embodiment will be described in the present embodiment. The same elements as those of the second embodiment are denoted by the same reference signs in the drawings, and the description thereof may be omitted in the description of the present embodiment.

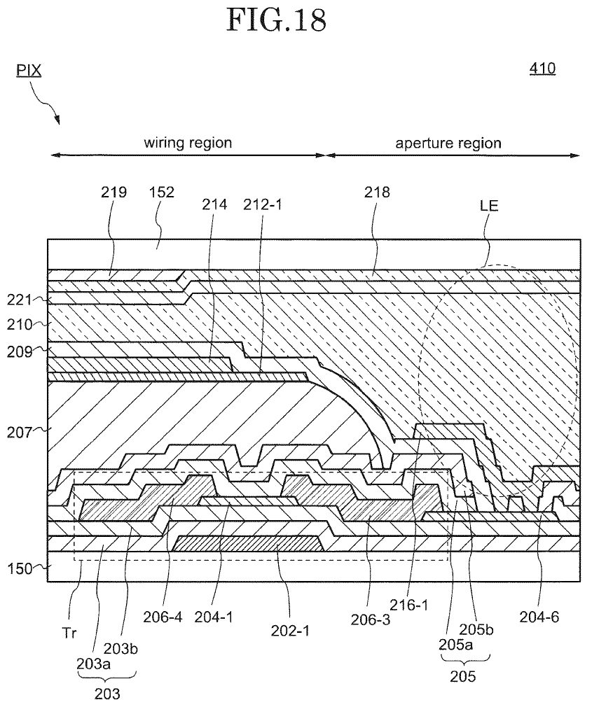

FIG. 18 is a cross-sectional view in the display device 410. The stacking order of the layers when the display device 410 is viewed in a cross-section will be described in FIG. 18.

As shown in FIG. 18, the conductive layer 208-1 (see FIG. 7 and FIG. 15) is not arranged on the insulating film 205. Therefore, the display device 410 does not include the back gate of the transistor Tr in the display devices 10 and 310. The planarization film 207 covers the insulating film 205.

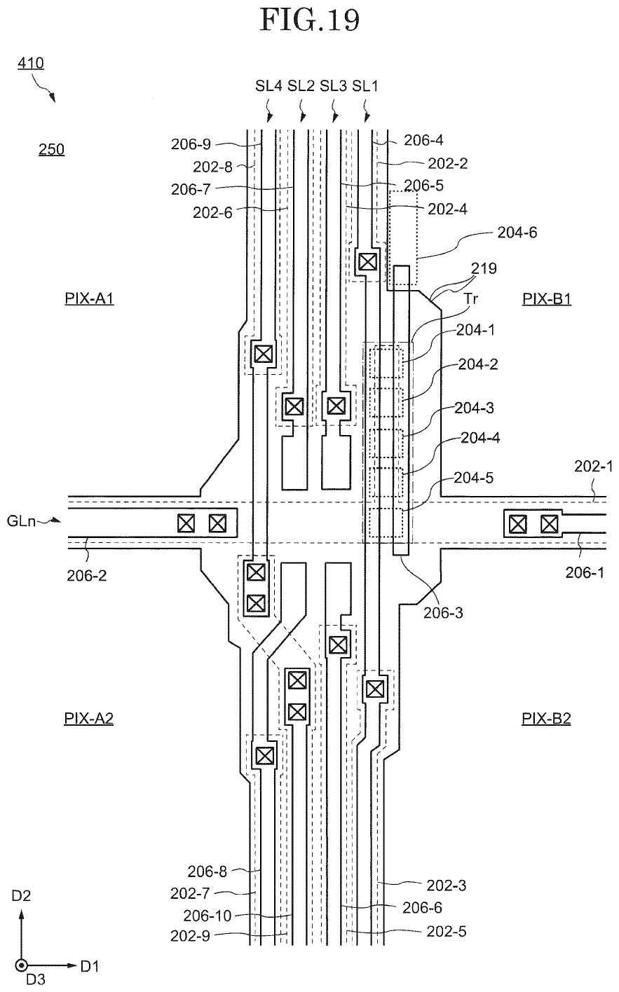

FIG. 19 is a planar layout of the conductive layers 202-1 to 202-9, the oxide semiconductor layers 204-1 to 204-6, the conductive layers 206-1 to 206-10, and the light-shielding layer 219 in the region 250. As shown in FIG. 19, the oxide semiconductor layers 204-1 to 204-6 are not in direct contact with each other. The conductive layer 206-3 extending in the direction D2 is arranged on the oxide semiconductor layers 204-1 to 204-6. The oxide semiconductor layer 204-6 is arranged in the opening region.

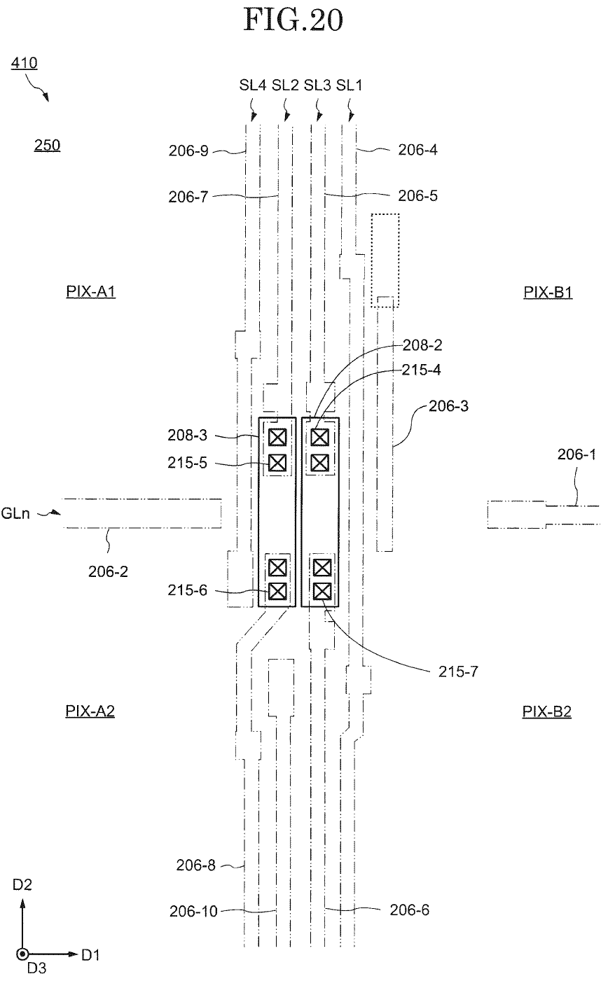

FIG. 20 is a planar layout of the oxide semiconductor layer 204-6, the conductive layers 206-1 to 206-10, and the conductive layers 208-2 and 208-3 in the region 250. As described above, the display device 410 does not include the back gate of the transistor Tr.

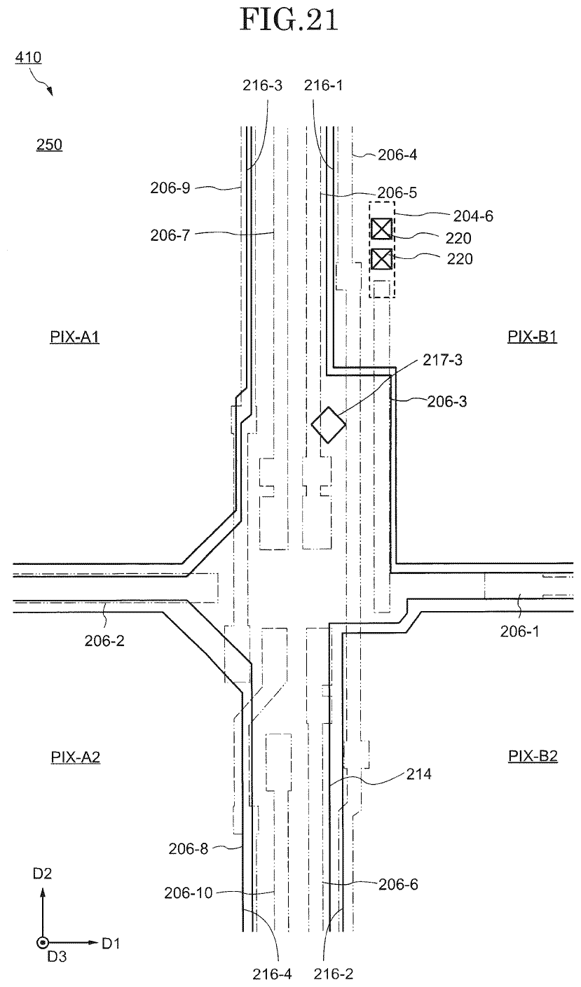

FIG. 21 is a planar layout of the conductive layers 206-1 to 206-10, the conductive layer 214, and the pixel electrodes 216-1 to 216-4 in the region 250. The pixel electrode 216-1 covers the oxide semiconductor layer 204-6. The pixel electrode 216-1 and the oxide semiconductor layer 204-6 are connected via the contact hole 220.

### Fourth Embodiment

Although the structure in which the oxide semiconductor layer 204-6 and the pixel electrode 216-1 are directly connected to each other has been described in the second embodiment, the oxide semiconductor layer 204-6 and the pixel electrode 216-1 may be electrically connected to each other via another conductive layer. A pixel electrode of a display device 510 according to the fourth embodiment has a structure in which the oxide semiconductor layer 204-6 and the pixel electrode 216-1 are connected to each other via another transparent conductive layer. Parts different from the display device 310 of the second embodiment will be described in the present embodiment. The same elements as those of the second embodiment are denoted by the same reference signs in the drawings, and the description thereof may be omitted in the description of the present embodiment.

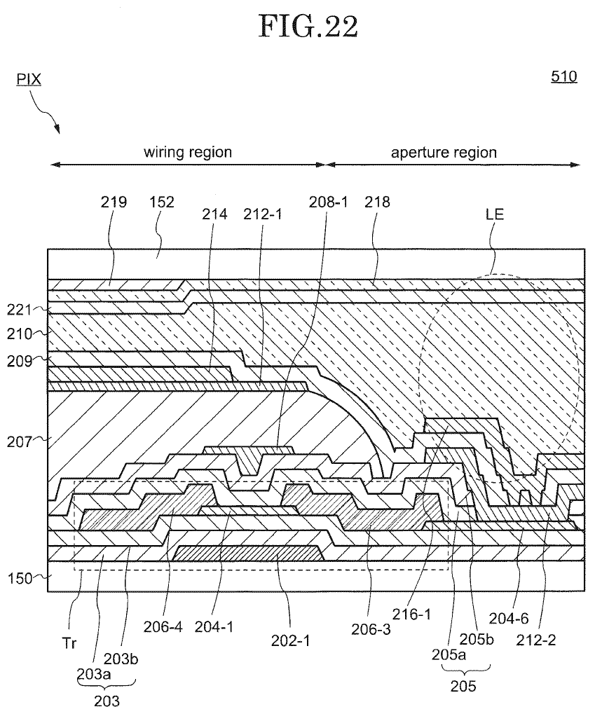

FIG. 22 is a cross-sectional view in the display device 510. The stacking order of the layers when the display device 510 is viewed in a cross-section will be described in FIG. 22.

As shown in FIG. 22, the pixel electrode 216-1 is connected to the transparent conductive layer 212-2 via the contact hole arranged in the insulating film 209. The transparent conductive layer 212-2 is in contact with the oxide semiconductor layer 204-6. The oxide semiconductor layer 204-6 is connected to the conductive layer 206-3. As described above, the pixel electrode 216-1 is in contact with the conductive layer 206-3 via the transparent conductive layer 212-2 and the oxide semiconductor layer 204-6.

A layer implanted with ions such as boron or a layer subjected to a plasma treatment under a hydrogen atmosphere can be used as the oxide semiconductor layer 204-6. Since the oxide semiconductor layer 204-6 approaches n-type by introducing hydrogen into the oxide semiconductor layer 204-6, the electric resistance decreases and has conductive properties. In this way, the resistance of the oxide semiconductor layer 204-6 in contact with the insulating film 209 is reduced and becomes an oxide conductive layer. The oxide semiconductor layer 204-6 may be formed of an amorphous material.

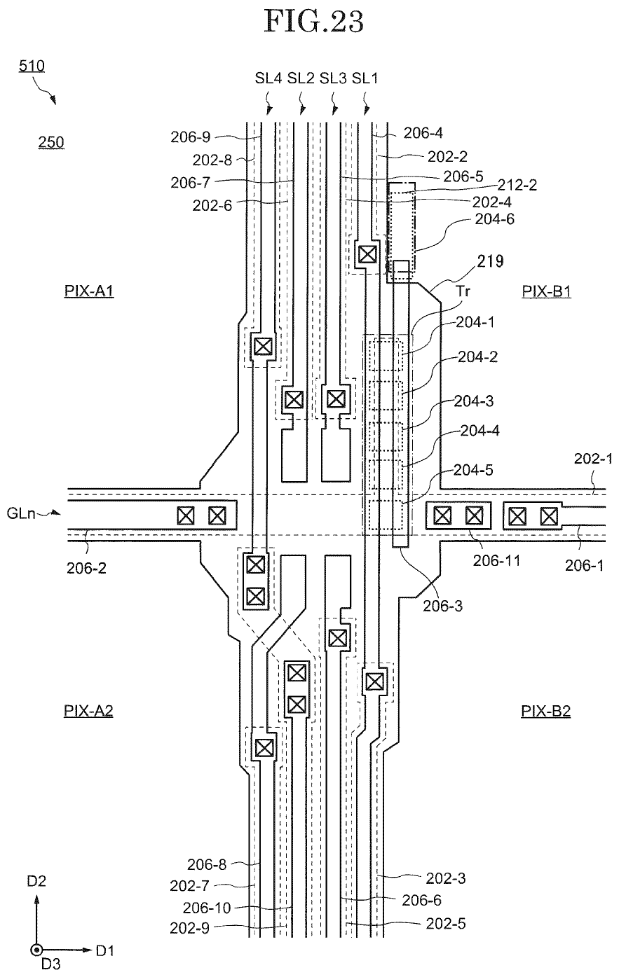

FIG. 23 is a planar layout of the conductive layers 202-1 to 202-9, the oxide semiconductor layers 204-1 to 204-6, the conductive layers 206-1 to 206-11, the transparent conductive layer 212-2, and the light-shielding layer 219 in the region 250. As shown in FIG. 23, the oxide semiconductor layer 204-6 extends in the direction D2. The transparent conductive layer 212-2 extends in the direction D2. A tip of the conductive layer 206-3 overlaps the oxide semiconductor layer 204-6. The oxide semiconductor layer 204-6 overlaps the transparent conductive layer 212-2.

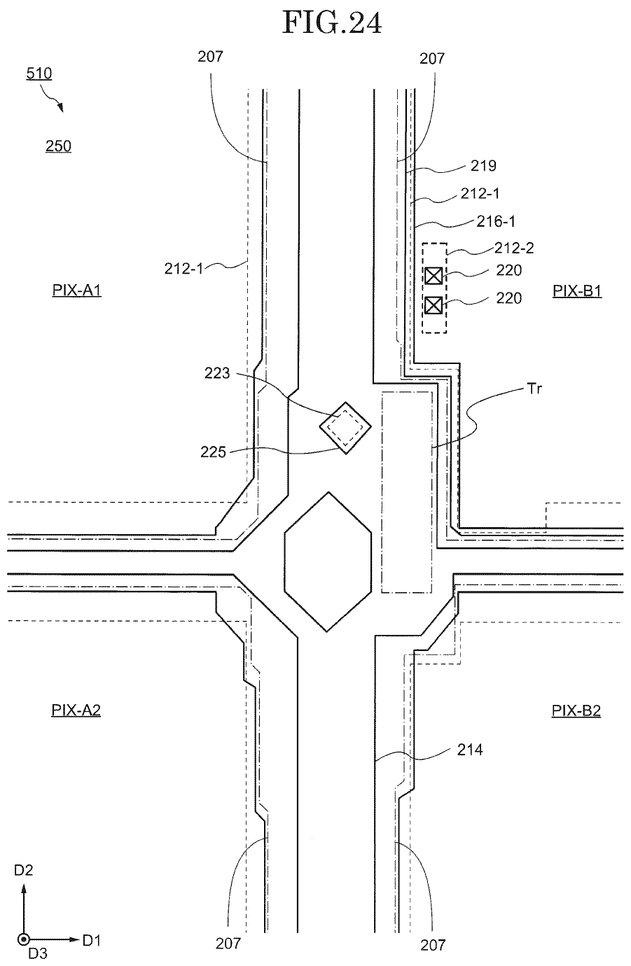

FIG. 24 is a planar layout of the planarization film 207, the transparent conductive layers 212-1 and 212-2, the conductive layer 214, and the light-shielding layer 219 in the region 250. As shown in FIG. 24, the transparent conductive layer 212-2 is covered with the pixel electrode 216-1. The transparent conductive layer 212-2 is connected to the pixel electrode 216-1 in the opening region via the contact hole 220.

### Fifth Embodiment

The drain electrode of the transistor Tr of the display devices 10, 310, 410, and 510 is formed by the conductive layer 206-3 (see FIG. 15), but the drain electrode of the transistor Tr may be an oxide conductive layer. Parts different from the display device 310 of the second embodiment will be described in the present embodiment. The same elements as those of the second embodiment are denoted by the same reference signs in the drawings, and the description thereof may be omitted in the description of the present embodiment. A pixel electrode of a display device 610 according to the fifth embodiment is not connected to the conductive layer 206-3, which is a drain-electrode, but is directly connected to the oxide semiconductor layer.

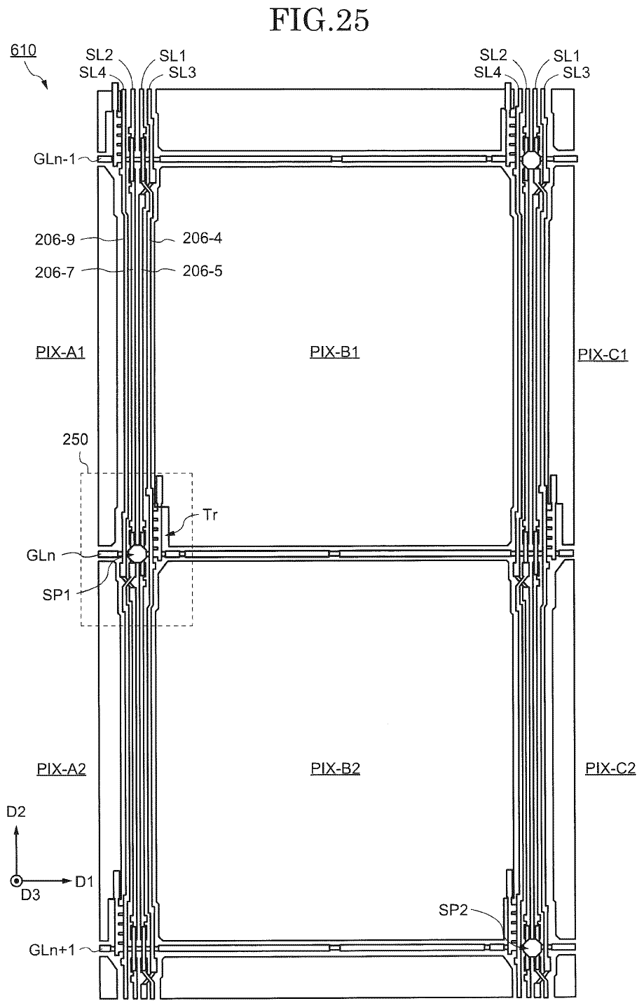

FIG. 25 shows a configuration in which the pixels PIX-A1, PIX-A2, PIX-B1, PIX-B2, PIX-C1, and PIX-C2 are in a plan view. As shown in FIG. 25, the transistor Tr of the display device 610 does not include the conductive layer 206-3 (see FIG. 6).

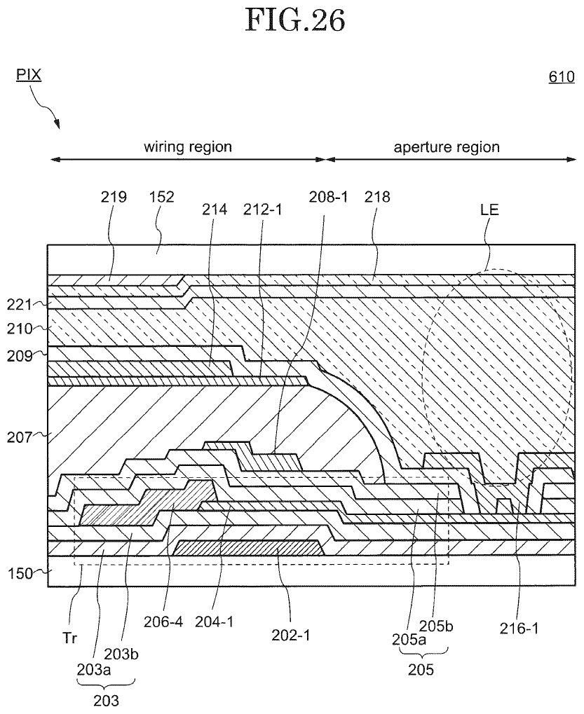

FIG. 26 is a cross-sectional view in the display device 610. The stacking order of the layers when the display device 610 is viewed in a cross-section will be described in FIG. 26.

As shown in FIG. 26, the gate insulating film 203 is arranged on the conductive layer 202-1. The oxide semiconductor layer 204-1 is arranged on the gate insulating film 203. The oxide semiconductor layer 204-1 extends from a position facing the conductive layer 202-1 via the gate insulating film 203 to the opening region. The insulating film 209 is arranged on the insulating film 205 in the opening region. The pixel electrode 216-1 is arranged on the insulating film 209. The pixel electrode 216-1 is in contact with the oxide semiconductor layer 204-1 in the opening region via the contact holes arranged in the insulating films 209 and 205, and is electrically connected to the oxide semiconductor layer 204-1.

The drain of the transistor Tr is formed by the oxide semiconductor layer 204-1. A layer implanted with ions such as boron or the like can be used as the oxide semiconductor layer 204-1. Since the oxide semiconductor layer 204-1 approaches n-type by implanting ions and introducing oxygen defects into the oxide semiconductor layer 204-1, the electric resistance decreases and has conductive properties. In this way, the resistance of the oxide semiconductor layer 204-1 is reduced and becomes an oxide conductive layer. In the case where a contact hole is formed in the insulating film 205 after the conductive layer 214 is formed, an amorphous material may be used as the oxide semiconductor layer 204-1.

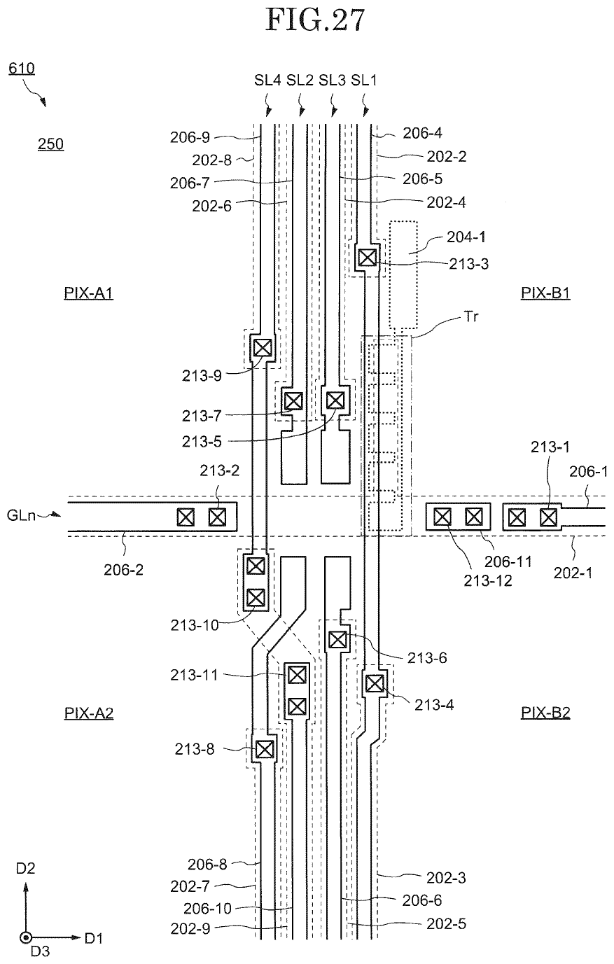

FIG. 27 is a planar layout of the conductive layers 202-1 to 202-9, the oxide semiconductor layer 204-1, and the conductive layers 206-1 to 206-11 in the region 250. As shown in FIG. 27, the oxide semiconductor layer 204-1 extends in the direction D1 and includes five regions overlapping the conductive layer 206-4 and a region contacting the five regions and extending in the direction D2.

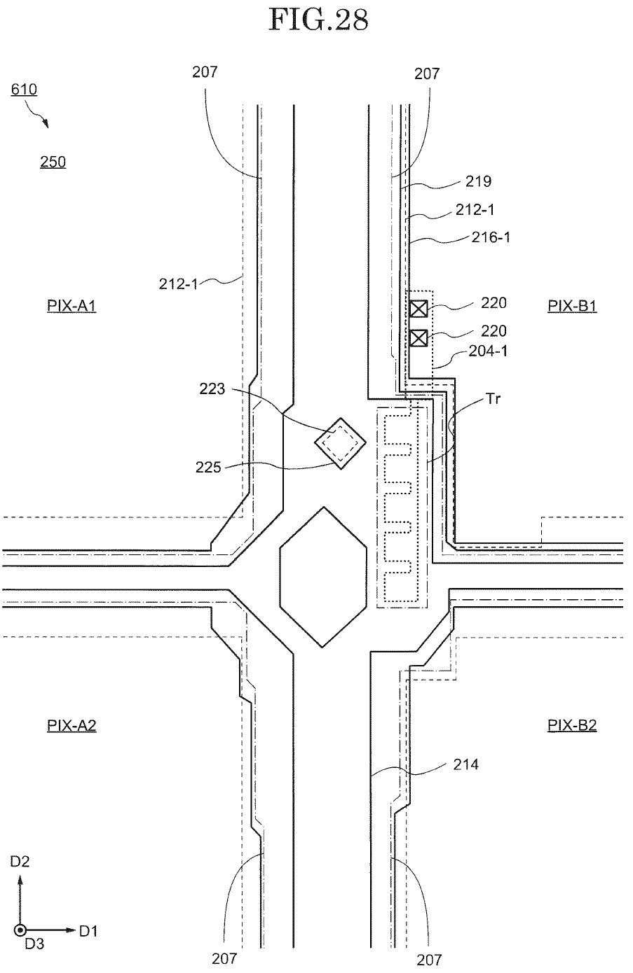

FIG. 28 is a planar layout of the planarization film 207, the transparent conductive layer 212-1, the conductive layer 214, the oxide semiconductor layer 204-1, and the light-shielding layer 219 in the region 250. As shown in FIG. 28, a region of the oxide semiconductor layer 204-1 extending in the direction D2 is in contact with the pixel electrode 216-1 in the opening region via the contact hole 220 arranged in the insulating film 209.

### Sixth Embodiment

Although the pixel electrode of the display device 610 is directly connected to the oxide semiconductor layer, the pixel electrode may be connected to the oxide semiconductor layer via another transparent conductive layer. A pixel electrode of a display device 710 according to the sixth embodiment is connected to the oxide semiconductor layer via a transparent conductive layer. Parts different from the display device 510 of the fourth embodiment will be described in the present embodiment. The same elements as those of the fourth embodiment are denoted by the same reference signs in the drawings, and the description thereof may be omitted in the description of the present embodiment.

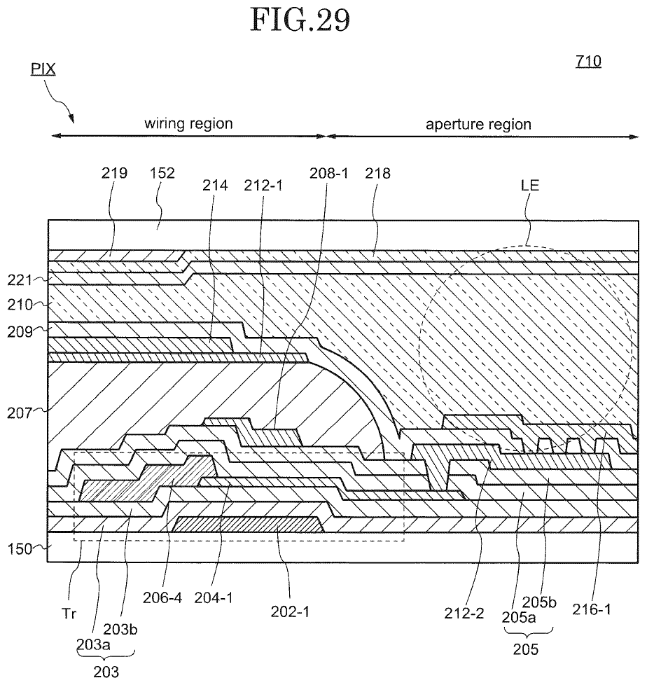

FIG. 29 is a cross-sectional view in the display device 710. The stacking order of the layers when the display device 710 is viewed in a cross-section will be described in FIG. 29.

As shown in FIG. 29, the oxide semiconductor layer 204-1 is arranged on the gate insulating film 203. The oxide semiconductor layer 204-1 extends from the wiring region to the opening region. The transparent conductive layer 212-2 is arranged on the oxide semiconductor layer 204-1 in the opening region. The insulating film 209 is formed on the transparent conductive layer 212-2. The pixel electrode 216-1 is arranged on the insulating film 209. The pixel electrode 216-1 is in contact with the transparent conductive layer 212-2 via the contact holes arranged in the insulating film 209. The transparent conductive layer 212-2 is in contact with the oxide semiconductor layer 204-1 via the contact holes arranged in the insulating film 205 in the opening region. As described above, the pixel electrode 216-1 is connected to the oxide semiconductor layer 204-1 via the transparent conductive layer 212-2.

The drain of the transistor Tr is formed by the oxide semiconductor layer 204-1. A layer implanted with ions such as boron or the like can be used as the oxide semiconductor layer 204-1. Since the oxide semiconductor layer 204-1 approaches n-type by implanting ions and introducing oxygen defects into the oxide semiconductor layer 204-1, the electric resistance decreases and has conductive properties. In this way, the resistance of the oxide semiconductor layer 204-1 is reduced and becomes an oxide conductive layer. An amorphous material may be used as the oxide semiconductor layer 204-1.

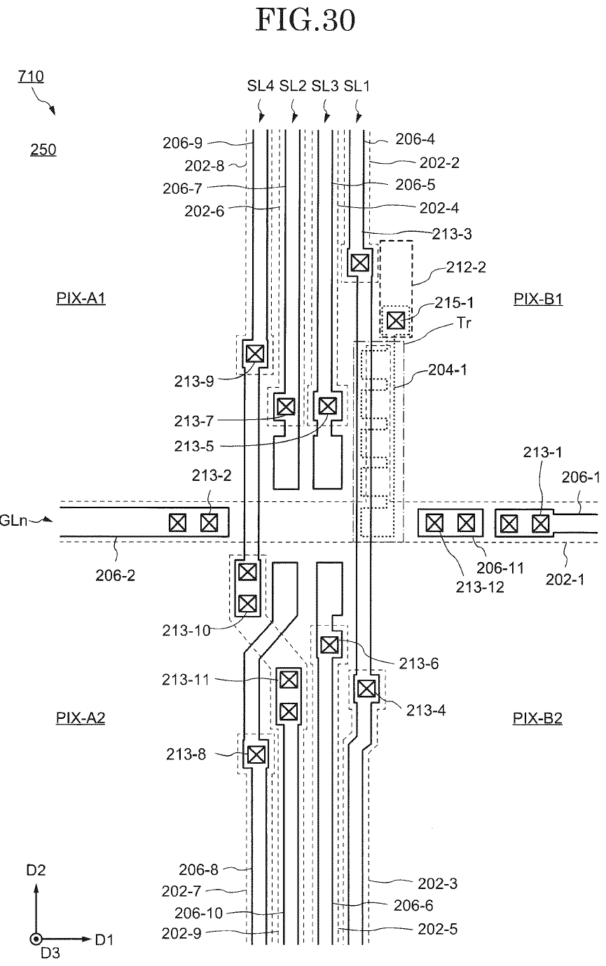

FIG. 30 is a planar layout of the conductive layers 202-1 to 202-9, the oxide semiconductor layer 204-1, the conductive layers 206-1 to 206-11, and the transparent conductive layer 212-2 in the region 250. As shown in FIG. 30, the oxide semiconductor layer 204-1 extends in the direction D2. The oxide semiconductor layer 204-1 is connected to the transparent conductive layer 212-2 via a contact hole 215-1 arranged in the insulating film 205.

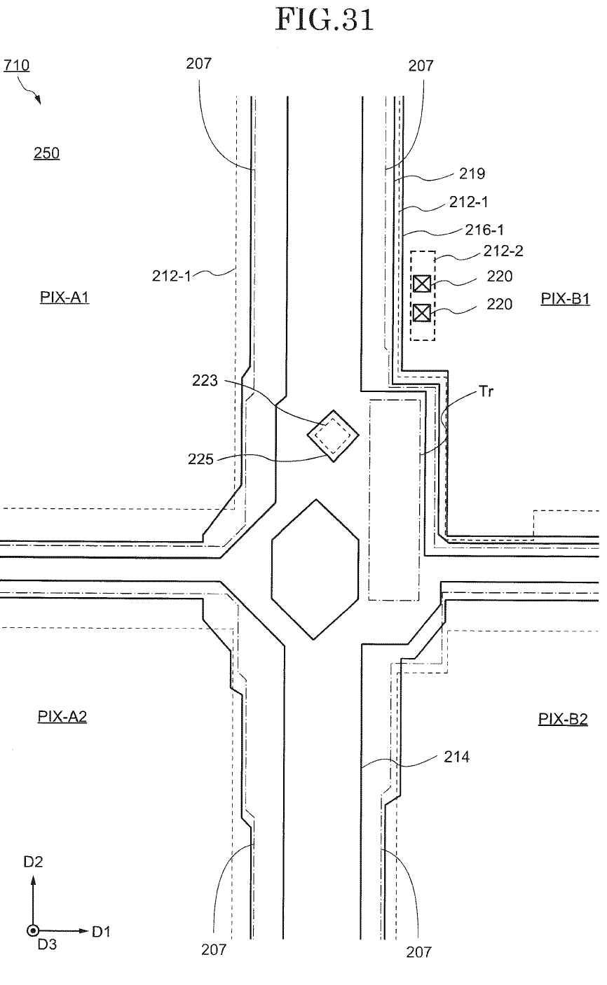

FIG. 31 is a planar layout of the planarization film 207, the transparent conductive layers 212-1 and 212-2, the conductive layer 214, and the light-shielding layer 219 in the region 250. As shown in FIG. 31, the transparent conductive layer 212-2 is covered with the pixel electrode 216-1. The transparent conductive layer 212-2 is connected to the pixel electrode 216-1 in the opening region via the contact hole 220 arranged in the insulating film 209.

### [Material of Each Member]

Hereinafter, materials of members commonly used in the display devices 10, 310, 410, 510, 610, and 710 will be described. A rigid substrate having light transmittance and no flexibility, such as a glass substrate, a quartz substrate, and a sapphire substrate can be used as the array substrate 150 and the counter substrate 152. On the other hand, in the case where the array substrate 150 and the counter substrate 152 need to have flexibility, a flexible substrate containing a resin and having flexibility, such as a polyimide substrate, an acryl substrate, a siloxane substrate, or a fluororesin substrate can be used as the array substrate 150 and the counter substrate 152. In order to improve the heat resistance of the array substrate 150 and the counter substrate 152, impurities may be introduced into the resin. In addition, in the case where the display devices 10, 310, 410, 510, 610, and 710 are applied to a transparent display or a large display, a glass substrate is preferably used as the array substrate 150 and the counter substrate 152. Further, the first transparent substrate 151A and the second transparent substrate 151B are arranged to protect the array substrate 150 and the counter substrate 152. For this reason, for example, it is preferable to use a glass substrate, a plastic substrate, or the like having light transmittance.

A single layer or stacked structure of silicon nitride (SiNₓ), silicon nitride oxide (SiNₓO_{y}), aluminum nitride (AlNₓ), aluminum nitride oxide (AlNₓO_{y}), silicon oxide (SiOₓ), silicon oxynitride (SiOₓN_{y}), aluminum oxide (AlOₓ), and aluminum oxynitride (AlOₓN_{y}) is used as the gate insulating film 203, the insulating film 205, and the insulating film 209. In the above embodiments, the gate insulating film 203 is configured by a stacked structure of the nitride insulating film 203a and the oxide insulating film 203b. In addition, the insulating film 205 is composed of the oxide insulating film 205a and the nitride insulating film 205b. Silicon nitride is used as the nitride insulating films 203a and 205b and the insulating film 209. For example, the silicon nitride film is formed by a chemical vapor phase deposition method. Silicon oxide is used as the insulating films 203b and 205a.

SiO_{X}N_{y} and AlOₓN_{y} are a silicon compound and aluminum compound containing a smaller proportion (x>y) of nitrogen (N) than oxygen (O). SiNₓO_{y} and AlNₓO_{y} are a silicon compound and aluminum compound containing a smaller proportion (x>y) of oxygen than nitrogen.

An organic insulating material such as a polyimide resin, an acryl resin, an epoxy resin, a silicone resin, a fluororesin, or a siloxane resin can be used as the planarization film 207.

Common metal materials can be used as the conductive layers 202, 206, and 208 and the conductive layer 214. For example, aluminum (Al), titanium (Ti), chromium (Cr), cobalt (Co), nickel (Ni), molybdenum (Mo), hafnium (Hf), tantalum (Ta), tungsten (W), bismuth (Bi), silver (Ag), copper (Cu), and an alloy or compound thereof are used as these members. The above-described materials may be used in a single layer or stacked layer.

An oxide semiconductor having semiconductor properties can be used as the oxide semiconductor layer 204. The oxide semiconductor layer 204 has light transmittance. For example, an oxide semiconductor containing two or more metals including indium (In) is used as oxide semiconductor layers 204. For example, an oxide semiconductor containing indium (In), gallium (Ga), zinc (Zn), and oxygen (O) may be used as the oxide semiconductor layer 204. In particular, an oxide semiconductor having a composition-ratio of In:Ga:Zn:O=1:1:1:4 may be used.

A mixture of indium oxide and tin oxide (ITO) and a mixture of indium oxide and zinc oxide (IZO) can be used as the transparent conductive layer 212, the pixel electrode 216, and the common electrode 218. A material other than the above may be used as the transparent conductive layer. The light-shielding layer 219 used as the black matrix BM can be formed of a black resin or metal material. The black matrix BM is formed in contact with the common electrode 218 (see FIG. 7). With respect to the common electrode 218 formed of the transparent conductive film, forming the black matrix BM with a metal material makes it possible to provide a function as an auxiliary electrode for reducing resistance dissipation. The metal material forming the black matrix BM may be used in a single layer or stacked layer of chrome, molybdenum, titanium, or the like having a relatively low reflectance compared with aluminum.

In the case where the display devices 10, 310, 410, 510, 610, and 710 are applied to a transparent display, a polymer-dispersed liquid crystal is preferably used as the liquid crystal layer 210. The polymer dispersed liquid crystal contains bulk and fine particles. The orientation of the fine particles varies in the bulk according to the potential difference between the pixel electrode 216 and the common electrode 218. Since the potential of the pixel electrode 216 is individually controlled for each pixel PIX, the degree of at least one of light transmission and distribution is controlled for each pixel PIX. The degree of scattering of the liquid crystal layer (fine particles) is controlled according to the voltage of the pixel electrode 216 and the voltage of the common electrode 218. For example, a polymer-dispersed liquid crystal, such as the degree of scattering increases as the voltage between the pixel PIX and the common electrode 218 increases, may be used for the liquid crystal layer. In addition, a polymer-dispersed liquid crystal, such as the degree of scattering increases as the voltage between the pixel electrode 216 and the common electrode 218 decreases, may be used for the liquid crystal layer.

The ordinary refractive indices of the bulk and fine particles are equal to each other in the liquid crystal layer 210. In the state where no voltage is applied between the pixel electrode 216 and the common electrode 218, the refractive index difference between the bulk and the fine particles is zero in all directions. The liquid crystal layer 210 is in the non-scattering state without scattering the light emitted from the light source. Light emitted from the light source propagates away from the light source 104 (light-emitting unit) while being reflected by a first main surface of the array substrate 150 and a first main surface of the counter substrate 152. In the state where the liquid crystal layer 210 is in the non-scattering state in which the light L emitted from a light source is not scattered, the background of the counter substrate 152 is visible from the array substrate 150, and the background of the array substrate 150 is visible from the counter substrate 152.

Between the pixel electrode 216 and the common electrode 218 to which a voltage is applied, the optical axis of the fine particles will be tilted by the electric field generated between the pixel electrode 216 and the common electrode 218. Since the optical axis of the bulk does not change depending on the electric field, orientations of the optical axis of the bulk and the optical axis of the fine particles are different from each other. In the pixel PIX of the pixel electrode 216 to which a voltage is applied, light emitted from the light source is scattered. A part of the light emitted from the light source which was scattered as described above is emitted to the outside from the first main surface of the array substrate 150 or the first main surface of the counter substrate 152 and observed by the observer.

In the pixel PIX of the pixel electrode 216 with no voltage applied, the background of the counter substrate 152 on the first main surface side is visible from the first main surface of the array substrate 150, and the background of the array substrate 150 on a first main surface 10A side of the array substrate 150 is visible from a first main surface 20A of the counter substrate 152. Then, in the display device 10 of the present embodiment, when the video signal is input, a voltage is applied to the pixel electrode 216 of the pixel PIX on which an image is displayed, and the image based on the video signal is visually recognized together with the background. In this way, when the polymer-dispersed liquid crystal is in a scattered state, images are displayed in the display region.

While preferred embodiments have been described above, the present invention is not limited to such embodiments. The contents disclosed in the embodiments are merely examples, and various changes can be made without departing from the spirit of the present invention. Appropriate changes that have been made without departing from the spirit of the present invention naturally fall within the technical scope of the present invention. In addition, each of the above-described embodiments can be appropriately combined as long as no contradiction is caused. Further, it is understood that, even if the effect is different from those provided by each of the above-described embodiments, the effect obvious from the description in the specification or easily predicted by persons ordinarily skilled in the art is apparently derived from the present invention.

What is claimed is:

1. A display device comprising:
a first conductive layer;
a first insulating film arranged on the first conductive layer;
an oxide semiconductor layer arranged on the first insulating film;
a second conductive layer arranged on the first insulating film and connected to the oxide semiconductor layer;
a planarization layer arranged on the oxide semiconductor layer;
a first transparent conductive layer in contact with the second conductive layer inside an opening in the planarization layer; and
a second transparent conductive layer in contact with the first transparent conductive layer inside the opening.

2. The display device according to claim 1, wherein the first transparent conductive layer is an oxide conductive layer.

3. The display device according to claim 1, wherein the display device further comprises a nitride insulating layer arranged on the planarization layer, and the first transparent conductive layer is in contact with the nitride insulating layer.

4. The display device according to claim 1, wherein the oxide semiconductor layer includes a crystal structure.

5. The display device according to claim 1, wherein the first transparent conductive layer is in contact with the second conductive layer inside the opening via a third transparent conductive layer.

6. The display device according to claim 5, wherein the third transparent conductive layer is an oxide conductive layer.

7. A display device comprising:
a first conductive layer;
a first insulating film arranged on the first conductive layer;
an oxide semiconductor layer arranged on the first insulating film;
a planarization layer arranged on the oxide semiconductor layer; and
a first transparent conductive layer electrically connected to the oxide semiconductor layer inside an opening in the planarization layer.

8. The display device according to claim 7, wherein the oxide semiconductor layer is in contact with the first transparent conductive layer inside the opening.

9. The display device according to claim 7, wherein the display device further comprises a second transparent conductive layer in contact with the oxide semiconductor layer inside the opening, and the second transparent conductive layer is in contact with the first transparent conductive layer inside the opening.
